(19) United States
(12) Patent Application Publication
(10) Pub. No.: US 2021/0159871 A1
(43) Pub. Date: May 27, 2021

(54) IMPEDANCE ADJUSTMENT METHOD AND SEMICONDUCTOR DEVICE

(71) Applicant: Sony Semiconductor Solutions Corporation, Kanagawa (JP)

(72) Inventors: Shogo Hachiya, Kanagawa (JP); Kenichi Maruko, Kanagawa (JP); Koki Uchino, Tokyo (JP); Makoto Imamura, Nagasaki (JP); Takamichi Iwaki, Nagasaki (JP); Nobuyuki Asai, Kanagawa (JP)

(21) Appl. No.: 17/045,557

(22) PCT Filed: Mar. 18, 2019
(86) PCT No.: PCT/JP2019/011129

§ 371 Date: Oct. 6, 2020

(30) Foreign Application Priority Data
Apr. 13, 2018 (JP) 2018-077340

(51) Int. Cl. H03H 7/38; H03K 19/00

(52) U.S. Cl. CPC H03H 7/38; H03K 19/0005

(57) ABSTRACT

A semiconductor device according to an embodiment of the present disclosure includes an output driver including a first variable resistor element, a replica circuit including a second variable resistor element and having the same configuration as the output driver, a first wiring line coupled to an output end of the replica circuit; a second wiring line electrically coupled to a first external terminal; and a comparator that compares a voltage of the first wiring line with a voltage of the second wiring line.

### TECHNICAL FIELD

The present disclosure relates to an impedance adjustment method and a semiconductor device.

### BACKGROUND ART

In high-speed interfaces, impedance matching technology between an input/output buffer and a transmission line is used to ensure waveform quality and take measures against EMI (Electro-Magnetic Interference).

### CITATION LIST

### Patent Literature

PTL 1: Japanese Unexamined Patent Application Publication No. H09-130229

PTL 2: Japanese Unexamined Patent Application Publication No. 2007-195168

PTL 3: Japanese Unexamined Patent Application Publication No. 2011-101143

PTL 4: Japanese Unexamined Patent Application Publication No. 2012-253485

PTL 5: Japanese Unexamined Patent Application Publication No. 2009-177594

### SUMMARY OF THE INVENTION

Incidentally, to perform impedance matching with high accuracy, it is conceivable that impedance variations in an output buffer and impedance variations in an input buffer are adjusted by trimming. In adjustment by trimming, it is desired to reduce trimming errors. It is therefore desirable to provide an impedance adjustment method and a semiconductor device that make it possible to reduce trimming errors.

A first impedance adjustment method according to an embodiment of the present disclosure is a method of adjusting an impedance of a first variable resistor element in a semiconductor device, the semiconductor device including an output driver, a replica circuit, a first wiring line, a second wiring line, and a comparator, the output driver including the first variable resistor element, the replica circuit including a second variable resistor element and having the same configuration as the output driver, the first wiring line coupled to an output end of the replica circuit, the second wiring line electrically coupled to a first external terminal, the comparator that compares a voltage of the first wiring line with a voltage of the second wiring line. The impedance adjustment method includes a step of: adjusting impedances of the second variable resistor element and the first variable resistor element on the basis of a comparison result, by the comparator, between a reference voltage and an output voltage of the replica circuit, the reference voltage being generated by coupling a first constant current source to the first external terminal.

In the first impedance adjustment method according to the embodiment, the impedances of the second variable resistor element and the first variable resistor element are adjusted on the basis of the comparison result, by the comparator, between the reference voltage, which is generated by coupling the first constant current source to the first external terminal, and the output voltage of the replica circuit. This makes it possible to adjust output impedances of the second variable resistor element and the first variable resistor element while avoiding an influence of a constant resistance.

A second impedance adjustment method according to an embodiment of the present disclosure is a method of adjusting an impedance of a first variable resistor element in a semiconductor device, the semiconductor device including an output driver, a replica circuit, a first wiring line, a second wiring line, a third wiring line, a reference resistor, a first selector, and a comparator, the output driver including the first variable resistor element, the replica circuit including a second variable resistor element and having the same configuration as the output driver, the first wiring line coupled to an output end of the replica circuit, the second wiring line electrically coupled to a first external terminal, the third wiring line electrically coupled to a second external terminal, the reference resistor including a third variable resistor element electrically coupled to a fourth wiring line, the first selector that selects one of the first wiring line and the third wiring line, and the fourth wiring line, the comparator that compares a voltage of the fourth wiring line with a voltage of the second wiring line. The impedance adjustment method includes: adjusting impedances of the second variable resistor element and the first variable resistor element on the basis of a first comparison result by the comparator and a second comparison result by the comparator. Here, the first comparison result is a result obtained by a comparison, by the comparator, between a reference voltage generated by coupling a first constant current source to the first external terminal, and a voltage generated by flowing, into the reference resistor, of a current via the third wiring line and the first selector, the current being generated by coupling a second constant current source to the second external terminal. The second comparison result is a result obtained by a comparison, by the comparator, between the reference voltage generated by coupling the first constant current source to the first external terminal, and an output voltage of the replica circuit obtained via the first selector and the fourth wiring line in a state in which the third variable resistor element is coupled to the fourth wiring line.

In the second impedance adjustment method according to the embodiment of the present disclosure, the impedances of the second variable resistor element and the first variable resistor element are adjusted on the basis of the above-described first comparison result by the comparator and the above-described second comparison result by the comparator. This makes it possible to adjust output impedances of the second variable resistor element and the first variable resistor element while avoiding an influence of a constant resistance.

A third impedance adjustment method is a method of adjusting an impedance of a first variable resistor element in a semiconductor device, the semiconductor device including an output driver, first and second replica circuits, a first wiring line, a second wiring line, a third wiring line, a first reference resistor, a second reference resistor, a fourth wiring line, a third reference resistor, a selector, and a comparator, the output driver including the first variable resistor element, the first and second replica circuits including a second variable resistor element and having the same configuration as the output driver, the first wiring line coupled to an output end of the first replica circuit, the second wiring line electrically coupled to a first external terminal, the third wiring line electrically coupled to a second external terminal, the first reference resistor including a third variable resistor element electrically coupled to the third wiring line, the second reference resistor including a fourth variable resistor element electrically coupled to the first wiring line, the fourth wiring line coupled to an output end of the second replica circuit, the third reference resistor including a fifth variable resistor element electrically coupled to the fourth wiring line, the selector that selects one of the first wiring line, the third wiring line, and a first constant voltage line and one of the second wiring line, the fourth wiring line, and a second constant voltage line, the comparator that compares two voltages outputted from the selector with each other. The impedance adjustment method includes: adjusting impedances of the second variable resistor element and the first variable resistor element on the basis of a first comparison result by the comparator, a second comparison result by the comparator, and a third comparison result by the comparator. Here, the first comparison result is a result obtained by a comparison, by the comparator, between a reference voltage generated by coupling a first constant current source to the first external terminal, and a voltage generated by flowing, into the first reference resistor, of a current generated by coupling a second constant current source to the second external terminal. The second comparison result is a result obtained by a comparison, by the comparator, between an output voltage of the first replica circuit in a state in which the fourth variable resistor element is coupled to the first wiring line, and a voltage of the second constant voltage line. The third comparison result is a result obtained by a comparison, by the comparator, between an output voltage of the second replica circuit in a state in which the fifth variable resistor element is coupled to the fourth wiring line, and a voltage of the first constant voltage line.

In the third impedance adjustment method according to the embodiment of the present disclosure, the impedances of the second variable resistor element and the first variable resistor element are adjusted on the basis of the above-described first comparison result by the comparator, the above-described second comparison result by the comparator, and the above-described third comparison result by the comparator. This makes it possible to adjust output impedances of the second variable resistor element and the first variable resistor element while avoiding an influence of a constant resistance.

A first semiconductor device according to an embodiment of the present disclosure includes: an output driver including a first variable resistor element; a replica circuit including a second variable resistor element and having the same configuration as the output driver; a first wiring line coupled to an output end of the replica circuit; a second wiring line electrically coupled to a first external terminal; and a comparator that compares a voltage of the first wiring line with a voltage of the second wiring line.

In the first semiconductor device according to the embodiment of the present disclosure, the comparator is provided. The comparator performs a comparison between a voltage of the first wiring line coupled to the output end of the replica circuit and a voltage of the second wiring line electrically coupled to the first external terminal. This makes it possible to adjust impedances of the second variable resistor element and the first variable resistor element on the basis of a comparison result, by the comparator, between the reference voltage generated by coupling a first constant current source to the first external terminal and the output voltage of the replica circuit.

A second semiconductor device according to an embodiment of the present disclosure includes: an output driver including a first variable resistor element; a replica circuit including a second variable resistor element and having the same configuration as the output driver; a first wiring line coupled to an output end of the replica circuit; a second wiring line electrically coupled to a first external terminal; a third wiring line electrically coupled to a second external terminal; a reference resistor including a third variable resistor element electrically coupled to a fourth wiring line; a first selector that selects one of the first wiring line and the third wiring line and the fourth wiring line; and a comparator that compares a voltage of the fourth wiring line with a voltage of the second wiring line.

In the second semiconductor device according to the embodiment of the present disclosure, the first selector selects one of the first wiring line and the third wiring line, and the comparator is provided. The comparator compares the voltage of the fourth wiring line electrically coupled to the reference resistor with the voltage of the second wiring line electrically coupled to the first external terminal. Thus, the impedances of the second variable resistor element and the first variable resistor element are adjusted on the basis of a first comparison result by the comparator and a second comparison result by the comparator, for example. Here, the first comparison result is a result obtained by a comparison, by the comparator, between a reference voltage generated by coupling a first constant current source to the first external terminal, and a voltage generated by flowing, into the reference resistor, of a current via the third wiring line and the first selector, the current being generated by coupling a second constant current source to the second external terminal. The second comparison result is a result obtained by a comparison, by the comparator, between the reference voltage generated by coupling the first constant current source to the first external terminal, and an output voltage of the replica circuit obtained via the first selector and the fourth wiring line in a state in which the third variable resistor element is coupled to the fourth wiring line. This makes it possible to adjust output impedances of the second variable resistor element and the first variable resistor element while avoiding an influence of a constant resistance.

A third semiconductor device according to an embodiment of the present disclosure includes: an output driver including a first variable resistor element; first and second replica circuits including a second variable resistor element and having the same configuration as the output driver; a first wiring line coupled to an output end of the first replica circuit; a second wiring line electrically coupled to a first external terminal; a third wiring line electrically coupled to a second external terminal; a first reference resistor including a third variable resistor element electrically coupled to a third wiring line; a second reference resistor including a fourth variable resistor element electrically coupled to the first wiring line; a fourth wiring line coupled to an output end of the second replica circuit; a third reference resistor including a fifth variable resistor element electrically coupled to the fourth wiring line; a selector that selects one of the first wiring line, the third wiring line, and a first constant voltage line and one of the second wiring line, the fourth wiring line, and a second constant voltage line; and a comparator that compares two voltages outputted from the selector with each other.

In the third semiconductor device according to the embodiment of the present disclosure, the comparator is provided. The comparator compares two voltages outputted from the selector with each other. The selector selects one of the first wiring line electrically coupled to the second reference resistor and coupled to the output end of the first replica circuit, the third wiring line electrically coupled to the first reference resistor and electrically coupled to the second external terminal, and the first constant voltage line, and one of the second wiring line electrically coupled to the first external terminal, the fourth wiring line electrically coupled to the third reference resistor and coupled to the output end of the second replica circuit, and the second constant voltage line. Thus, impedances of the second voltage resistor element and the first variable resistor element are adjusted on the basis of a first comparison result by the comparator, a second comparison result by the comparator, and a third comparison result by the comparator. Here, the first comparison result is a result obtained by a comparison, by the comparator, between a reference voltage generated by coupling a first constant current source to the first external terminal, and a voltage generated by flowing, into the first reference resistor, of a current generated by coupling a second constant current source to the second external terminal. The second comparison result is a result obtained by a comparison, by the comparator, between an output voltage of the first replica circuit in a state in which the fourth variable resistor element is coupled to the first wiring line, and a voltage of the second constant voltage line. The third comparison result is a result obtained by a comparison, by the comparator, between an output voltage of the second replica circuit in a state in which the fifth variable resistor element is coupled to the fourth wiring line, and a voltage of the first constant voltage line. This makes it possible to adjust output impedances of the second variable resistor element and the first variable resistor element while avoiding an influence of a constant resistance.

### BRIEF DESCRIPTION OF DRAWINGS

FIG. 1 illustrates a schematic configuration example of a transmitter according to a first embodiment of the present disclosure.

FIG. 2A illustrates an example of a circuit configuration of an output driver in FIG. 1.

FIG. 2B illustrates an example of the circuit configuration of the output driver in FIG. 1.

FIG. 2C illustrates an example of the circuit configuration of the output driver in FIG. 1.

FIG. 2D illustrates an example of the circuit configuration of the output driver in FIG. 1.

FIG. 3A illustrates an example of a circuit configuration of a replica circuit in FIG. 1.

FIG. 3B illustrates an example of the circuit configuration of the replica circuit in FIG. 1.

FIG. 3C illustrates an example of the circuit configuration of the replica circuit in FIG. 1.

FIG. 3D illustrates an example of the circuit configuration of the replica circuit in FIG. 1.

FIG. 4 illustrates an example of a circuit configuration of a trimming circuit in FIG. 1.

FIG. 5 is a flowchart illustrating an example of an output impedance adjustment procedure in the transmitter in FIG. 1.

FIG. 6 illustrates a modification example of a schematic configuration of the transmitter in FIG. 1.

FIG. 7 illustrates an example of a circuit configuration of the trimming circuit in FIG. 6.

FIG. 8 is a flowchart illustrating an example of an output impedance adjustment procedure in the transmitter in FIG. 6.

FIG. 9 illustrates a modification example of a schematic configuration of the transmitter in FIG. 1.

FIG. 10 illustrates an example of a circuit configuration of the trimming circuit in FIG. 9.

FIG. 11 is a flowchart illustrating an output impedance adjustment procedure in the transmitter including the trimming circuit in FIG. 9.

FIG. 12 is a schematic view of an example of the output impedance adjustment procedure in the transmitter including the trimming circuit in FIG. 9.

FIG. 13 is a schematic view of an example of the adjustment procedure subsequent to FIG. 11.

FIG. 14 is a schematic view of an example of the adjustment procedure subsequent to FIG. 13.

FIG. 15 illustrates a modification example of a circuit configuration of the trimming circuit in FIG. 10.

FIG. 16 illustrates a modification example of a schematic configuration of the transmitter in FIG. 1.

FIG. 17 illustrates a modification example of a schematic configuration of the transmitter in FIG. 1.

FIG. 18 illustrates a modification example of a circuit configuration of the trimming circuit in FIG. 17.

FIG. 19 illustrates a modification example of a schematic configuration of the transmitter in FIG. 6.

FIG. 20 illustrates a modification example of a circuit configuration of the trimming circuit in FIG. 19.

FIG. 21 illustrates a modification example of a schematic configuration of the transmitter in FIG. 16.

FIG. 22 illustrates a schematic configuration example of a receiver according to a second embodiment of the present disclosure.

FIG. 23 illustrates a schematic configuration example of a communication system according to a third embodiment of the present disclosure.

FIG. 24 illustrates an example of an appearance configuration of a smartphone to which the above-described communication system is applied.

FIG. 25 illustrates a configuration example of an application processor to which the above-described communication system is applied.

FIG. 26 illustrates a configuration example of an image sensor to which the above-described communication system is applied.

FIG. 27 illustrates an installation example of a vehicle-mounted camera to which the above-described communication system is applied.

FIG. 28 illustrates a configuration example in which the above-described communication system is applied to the vehicle-mounted camera.

### MODES FOR CARRYING OUT THE INVENTION

In the following, some embodiments of the present disclosure are described in detail with reference to the drawings. It is to be noted that description is given in the following order.

### 1. First Embodiment (Transmitter)

### 2. Modification Examples of First Embodiment (Transmitter)

### 3. Second Embodiment (Receiver)

### 4. Third Embodiment (Communication System)

### 5. Application Examples

### 1. First Embodiment

### [Configuration]

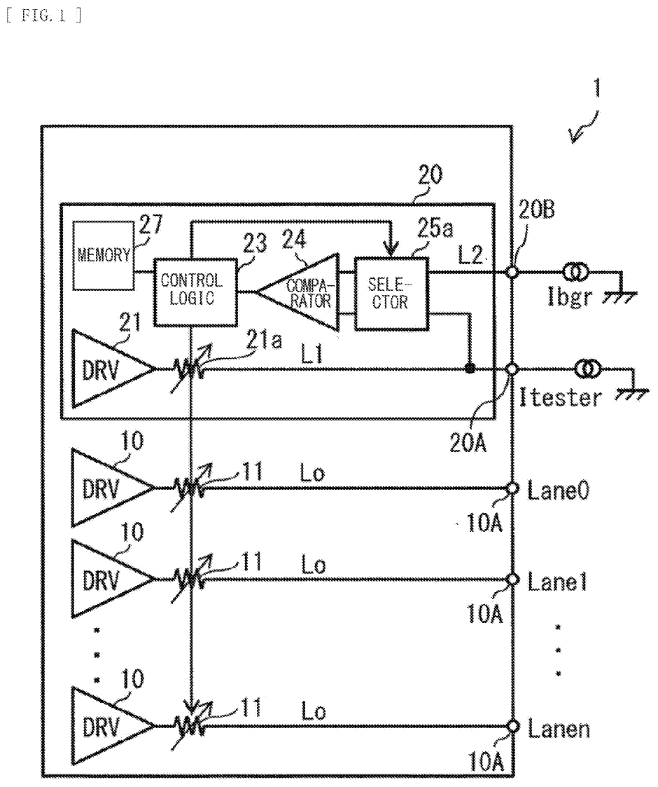

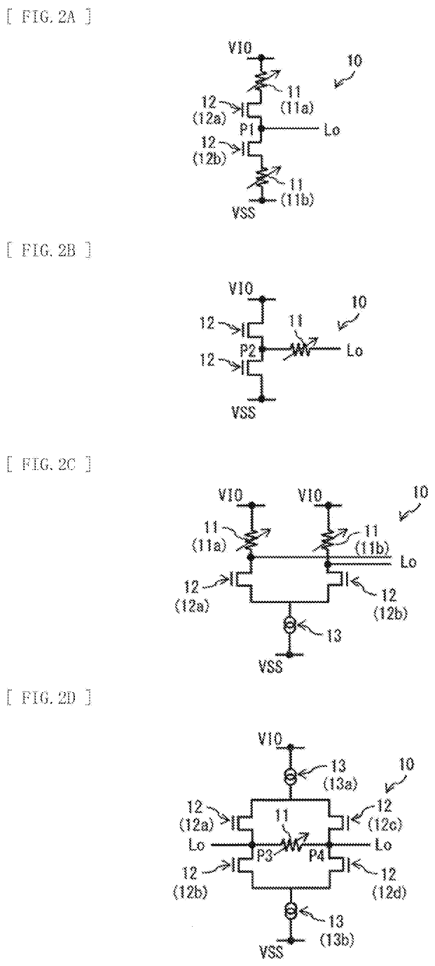

Description is given of a transmitter 1 according to a first embodiment of the present disclosure. FIG. 1 illustrates a schematic configuration example of the transmitter 1. The transmitter 1 includes a plurality of the output drivers 10, and a trimming circuit 20. The output drivers 10 each have, for example, a circuit configuration applicable to a push-pull current output as illustrated in FIG. 2A, FIG. 2B, FIG. 2C, and FIG. 2D.

For example, as illustrated in FIG. 2A, the output driver 10 is a circuit in which a variable resistor element 11 (11a) (a first variable resistor element) and a transistor 12 (12a) coupled to each other in series are inserted between a fixed voltage line VIO and an output line Lo of the output driver 10, and the variable resistor element 11 (11b) (the first variable resistor element) and the transistor 12 (12b) coupled to each other in series are inserted between a fixed voltage line VSS and the output line Lo of the output driver 10. The output line Lo of the output driver 10 is coupled to a coupling point P1 of the two transistors 12 (12a and 12b) (an output end of the output driver 10). One end of the output line Lo is coupled to the coupling point P1, another end of the output line Lo is coupled to an external terminal 10A.

For example, as illustrated in FIG. 2B, the output driver 10 may be a circuit in which two transistors 12 coupled to each other in series are inserted between the fixed voltage line VIO and the fixed voltage line VSS, and the variable resistor element 11 (the first variable resistor element) is inserted between a coupling point P2 of the two transistors 12 coupled to each other in series, and the output line Lo of the output driver 10. The output line Lo of the output driver 10 is coupled to the coupling point P2 of the two transistors 12. One end of the output line Lo is coupled to the coupling point P2, another end of the output line Lo is coupled to the external terminal 10A.

For example, as illustrated in FIG. 2C, the output driver 10 may be a circuit in which the variable resistor element 11 (11a) (the first variable resistor) and the transistor 12 (12a) coupled to each other in series, and the variable resistor element 11 (11b) (the first variable resistor element) and the transistor 12 (12b) coupled to each other in series are inserted in parallel between the fixed voltage line VIO and a current source 13.

For example, as illustrated in FIG. 2D, the output driver 10 may include a circuit in which two transistors 12 (12a and 12b) coupled to each other in series, and two transistors (12c and 12d) coupled to each other in series are coupled to each other in parallel and inserted between two current sources 13 (13a and 13b); the variable resistor element 11 (the first variable resistor element) is coupled to a coupling point P3 of the two transistors 12 (12c and 12d) and a coupling point P4 of the two transistors 12 (12c and 12d); and furthermore, one (13a) of the current sources 13 is coupled to the fixed voltage line VIO and the other current source 13 (13b) is coupled to the fixed voltage line VSS.

The trimming circuit 20 is a circuit that adjusts an output impedance of the output driver 10 to perform impedance matching between the output driver 10 and a transmission line. The trimming circuit 20 outputs an impedance code Code to the output driver 10 to thereby control the output impedance of the output driver 10.

The trimming circuit 20 includes, for example, a replica circuit 21 having the same configuration as that of the output driver 10. The trimming circuit 20 further includes, for example, a control logic 23 (a control circuit), a comparator 24, a selector 25a, and a memory 27. An initial value of the impedance code Code is stored in the memory 27. A set value of the impedance code Code derived by the control logic 23 is further stored in the memory 27. A constant current source is coupled to each of external terminals 20A and 20B of the trimming circuit 20 on an as-needed basis.

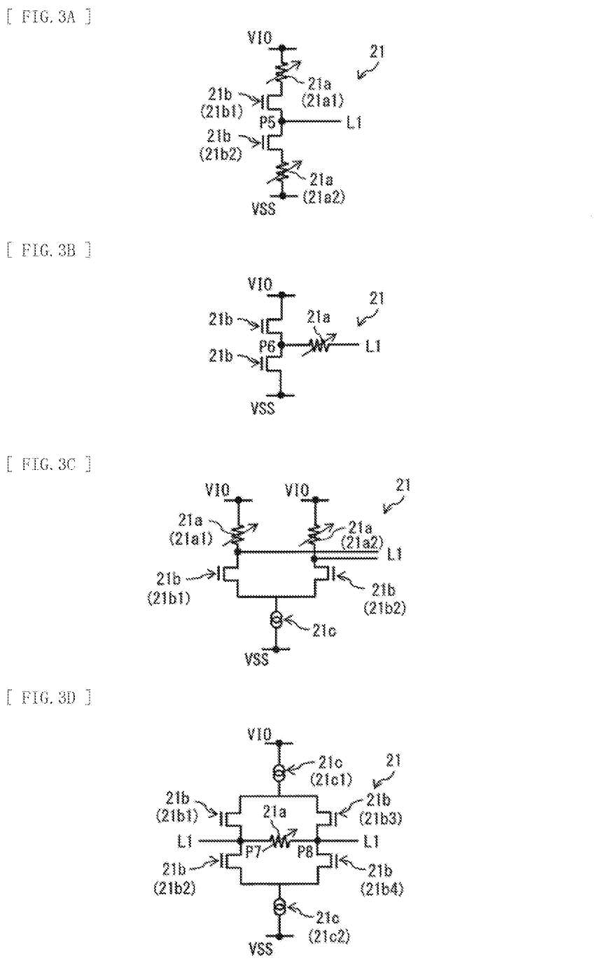

The replica circuit 21 has the same configuration as the output driver 10. The replica circuit 21 has, for example, a circuit configuration applicable to a push-pull current output as illustrated in FIG. 3A, FIG. 3B, FIG. 3C, and FIG. 3D.

For example, as illustrated in FIG. 3A, the replica circuit 21 is a circuit in which a variable resistor element 21a (21a1) (a second variable resistor element) and a transistor 21b (21b1) coupled to each other in series are inserted between the fixed voltage line VIO and the output line L1 of the replica circuit 21, and the variable resistor element 21a (21a2) (the second variable resistor element) and the transistor 21b (21b2) coupled to each other in series are inserted between the fixed voltage line VSS and the output line L1 of the replica circuit 21. The output line L1 of the replica circuit 21 is electrically coupled to a coupling point P5 (an output end) of the two transistors 21b (21b1 and 21b2).

For example, as illustrated in FIG. 3B, the replica circuit 21 may be a circuit in which two transistors 21b coupled to each other in series are inserted between the fixed voltage line VIO and the fixed voltage line VSS, and the variable resistor element 21a (the second variable resistor element) is inserted between a coupling point P6 of the two transistors 21b coupled to each other in series, and the output line L1 of the replica circuit 21. The output line L1 of the replica circuit 21 is coupled to the coupling point P6 of the two transistors 21b.

For example, as illustrated in FIG. 3C, the replica circuit 21 may be a circuit in which the variable resistor element 21a (21a1) (the second variable resistor element) and the transistor 21b (21b1) coupled to each other in series, and the variable resistor element 21a (21a2) (the second variable resistor element) and the transistor 21b (21b2) coupled to each other in series are inserted in parallel between the fixed voltage line VIO and a current source 21c.

For example, as illustrated in FIG. 3D, the replica circuit 21 may be a circuit in which two transistors 21b (21b1 and 21b2) coupled to each other in series, and two transistors 21b (21b3 an, 21b4) coupled to each other in series are coupled to each other in parallel and inserted between two current sources 21c (21c1 and 21c2); the variable resistor element 21a (the second variable resistor element) is coupled to a coupling point P7 of two transistors 21b (21b1 and 21b2) and a coupling point P8 of two transistors 21b (21b3 and 21b4); and furthermore, one (21c1) of the current sources 21c is coupled to the fixed voltage line VIO and the other current source 21c (21c2) is coupled to the fixed voltage line VSS.

The control logic 23 adjusts an output impedance of the replica circuit 21. The control logic 23 controls the replica circuit 21 and the selector 25a to thereby derive the impedance code Code for adjusting the output impedance of the replica circuit 21. The control logic 23 stores the derived impedance code Code in the memory 27. The control logic 23 further adjusts the output impedance of the output driver 10. The control logic 23 adjusts the output impedance of the output driver 10 with use of the impedance code Code read from the memory 27.

The selector 25a has two input terminals and two output terminals. The selector 25a interchanges coupling relations between the two input terminals of the selector 25a and the two output terminals of the selector 25a (i.e., two input terminals of the comparator 24) by control by the control logic 23. The selector 25a interchanges input points, to the comparator 24, of a voltage (=an output voltage V21) of the output line L1 of the replica circuit 21 and a voltage (=a reference voltage Vref) of the output line L2. The comparator 24 outputs, to the control logic 23, a difference between two signals inputted via the selector 25a.

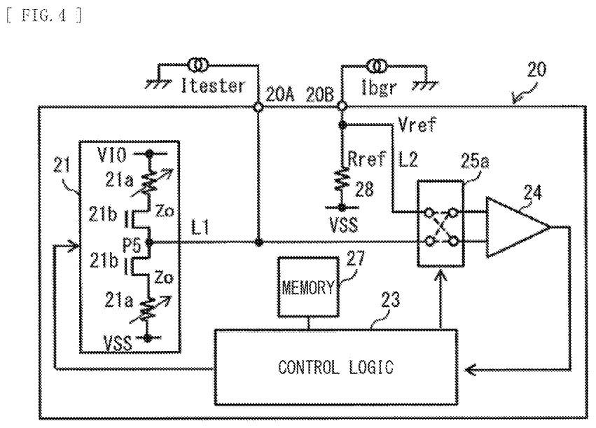

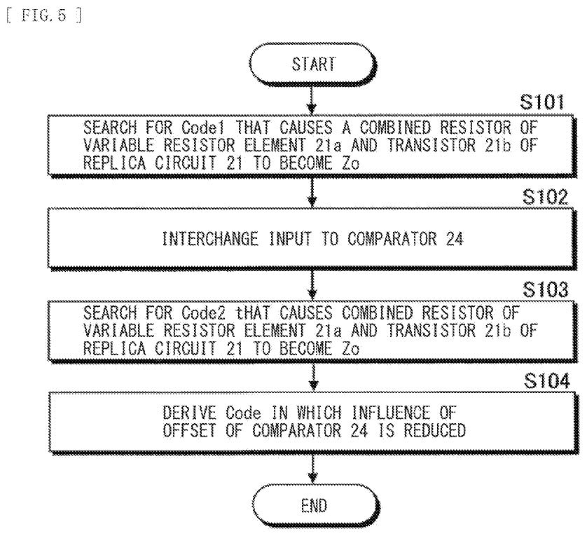

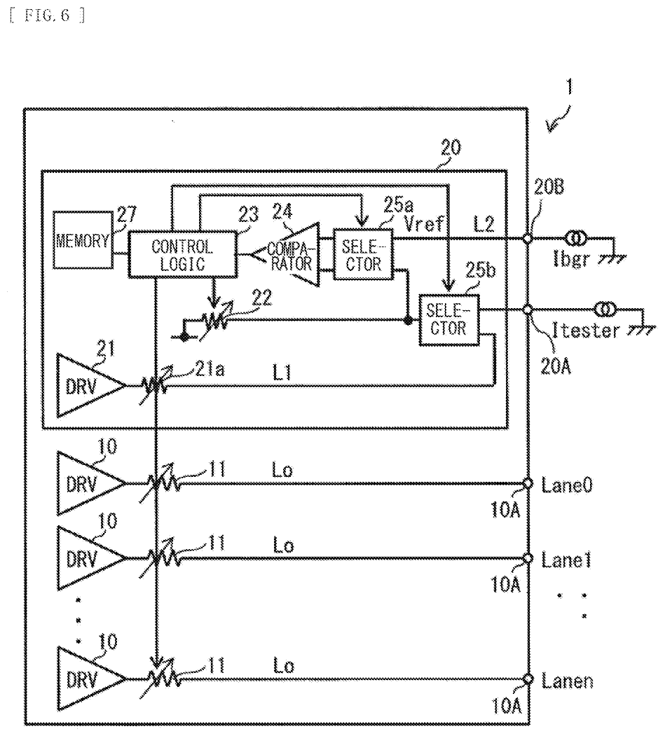

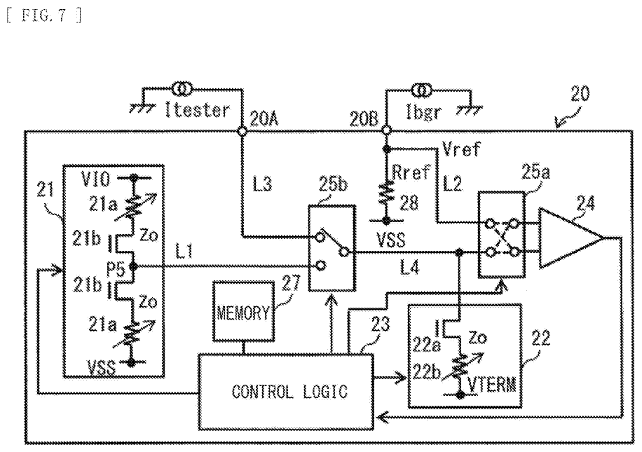

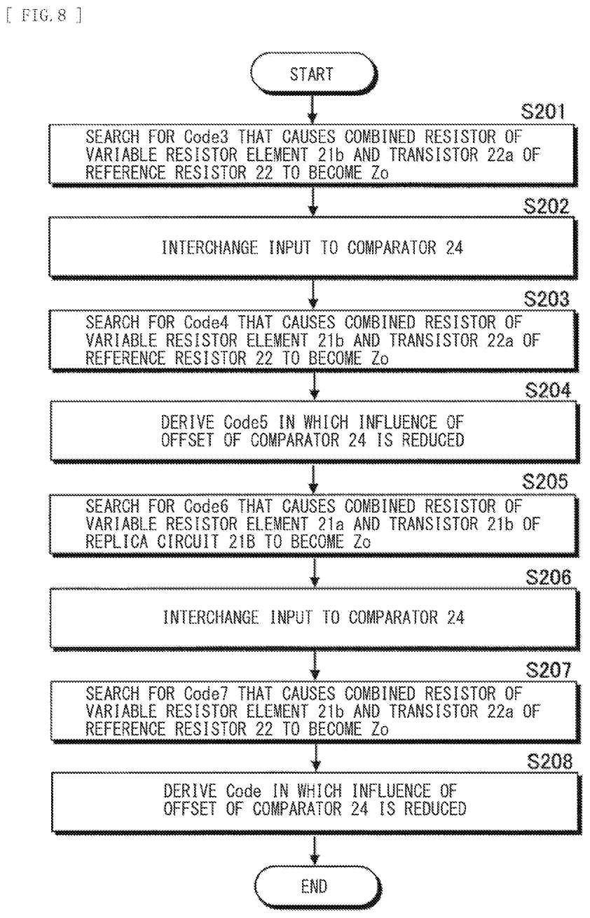

FIG. 4 illustrates an example of a circuit configuration of the trimming circuit 20. The trimming circuit 20 is not limited to the circuit configuration illustrated in FIG. 4. The trimming circuit 20 includes, for example, the replica circuit 21, the control logic 23, the comparator 24, the selector 25a, the memory 27, and a reference resistor element 28.

The replica circuit 21 illustrated in FIG. 4 has, for example, a circuit configuration illustrated in FIG. 3A. The replica circuit 21 is not limited to the circuit configuration illustrated in FIG. 3A, and as long as the replica circuit 21 has the same configuration as the output driver 10, the replica circuit 21 may have any circuit configuration. In the replica circuit 21, the transistor 21b is turned on and off by control by the control logic 23, and a resistance value R21a of the variable resistor element 21a is set to a predetermined value. For example, in a case where the transistor 21b is in an on state, the resistance value R21a of the variable resistor element 21a is set to a value that causes a resistance value between the fixed voltage line VIO or the fixed voltage line VSS and the coupling point P5 of two transistors 21b to become Zo, for example.

The reference resistor element 28 is inserted between the external terminal 20B and the fixed voltage line VSS. The reference resistor element 28 is electrically coupled to the external terminal 20B and the fixed voltage line VSS. A resistance value Rref of the reference resistor element 28 is Zo, for example. In a case where the output impedance of the replica circuit 21 is adjusted, a constant current source Ibgr that supplies a constant current is coupled to the external terminal 20B.

The selector 25a has two input terminals and two output terminals. One of the input terminals of the selector 25a, the coupling point P5 of the replica circuit 21, and the external terminal 20A are electrically coupled to one another via the output line L1. The other input terminal of the selector 25a and the external terminal 20B are electrically coupled to each other via the output line L2. The two output terminals of the selector 25a are coupled to two input terminals of the comparator 24. In a case where the output impedance of the replica circuit 21 is adjusted, a constant current source Itester that supplies a constant current is coupled to the external terminal 20A. In the selector 25a, coupling relations between the two input terminals of the selector 25a and the two output terminals of the selector 25a (i.e., the two input terminals of the comparator 24) are interchanged by control by the control logic 23.

### [Impedance Adjustment]

Next, description is given of output impedance adjustment in the transmitter 1. FIG. 5 illustrates an example of a output impedance adjustment procedure in the transmitter 1.

First, the control logic 23 searches for an impedance code Code1 that causes a combined resistor of the variable resistor element 21a and the transistor 21b of the replica circuit 21 to become Zo (step S101). Specifically, first, a user couples the constant current source Itester that supplies a constant current to the external terminal 20A, and couples the constant current source Ibgr that supplies a constant current to the external terminal 20B. Subsequently, the control logic 23 outputs an on signal to the transistor 21b on the fixed voltage line VSS side of the replica circuit 21, and inputs an initial value of the impedance code Code1 to the variable resistor element 21a on the fixed voltage line VSS side of the replica circuit 21. This turns on the transistor 21b on the fixed voltage line VSS side of the replica circuit 21, and sets a resistance value R21a of the variable resistor element 21a on the fixed voltage line VSS side of the replica circuit 21 to a resistance value R0 corresponding to the initial value of the impedance code Code1. Furthermore, a predetermined constant current from the constant current source Itester coupled to the external terminal 20A is supplied to the variable resistor element 21a on the fixed voltage line VSS side of the replica circuit 21, and a predetermined constant current from the constant current source Ibgr coupled to the external terminal 20B is supplied to the reference resistor element 28. As a result, the output voltage V21 of the replica circuit 21 (=a voltage V20A of the external terminal 20A) becomes a predetermined voltage value (Itester×(R0+Rtr)), and the voltage V20B of the external terminal 20B becomes a predetermined voltage value (Ibgr×Rref=the reference voltage Vref). It is to be noted that Rtr is a resistance value between a source and a drain of the transistor 21b in the on state on the fixed voltage line VSS side of the replica circuit 21. The voltage (=the output voltage V21) of the output line L1 and the voltage (=the reference voltage Vref) of the output line L2 are inputted to the comparator 24, and a signal corresponding to a voltage ΔV1 (=V21−Vref) of a difference between these voltages is inputted from the comparator 24 to the control logic 23. The control logic 23 sets the impedance code Code1 to a value that causes the voltage ΔV1 to approach zero, and outputs the value after such setting to the variable resistor element 21a on the fixed voltage line VSS side of the replica circuit 21. The control logic 23 resets the impedance code Code1 until the voltage ΔV1 becomes zero (or a value close to zero and within an allowable range). Consequently, when the voltage ΔV1 becomes zero (or the value close to zero and within the allowable range), the control logic 23 stores the set value at that time as the impedance code Code1 in the memory 27. Thus, the control logic 23 searches for the impedance code Code1 that causes the combined resistor of the variable resistor element 21a and the transistor 21b of the replica circuit 21 to become Zo.

Next, the control logic 23 interchanges input to the comparator 24 (step S102). Specifically, the control logic 23 inputs a control signal to the selector 25 to thereby interchange the coupling relations between the two input terminals of the selector 25 and the two output terminals of the selector 25 (i.e., the two input terminals of the comparator 24).

The control logic 23 then searches for an impedance code Code2 that causes the combined resistor of the variable resistor element 21a and the transistor 21b of the replica circuit 21 to become Zo, by a method similar to the step S101 (step S103). Thereafter, the control logic 23 derives, on the basis of the impedance codes Code1 and Code2, the impedance code Code in which an influence of an offset of the comparator 24 is reduced (step S104). The control logic 23 derives the impedance code Code in which the influence of the offset of the comparator 24 is reduced, with use of the following expression, for example.

Code=Code1−(Code1−Code2)/2

The control logic 23 stores the derived impedance code Code in the memory 27. The control logic 23 outputs the impedance code Code read from the memory 27 to the output driver 10 to thereby control (adjust) the output impedance of the output driver 10 (e.g., the variable resistor element 11).

### [Effects]

Next, description is given of effects of the transmitter 1 according to the present embodiment.

In high-speed interfaces, impedance matching technology between an input/output buffer and a transmission line is used to ensure waveform quality and take measures against EMI (Electro-Magnetic Interference).

Incidentally, to perform impedance matching with high accuracy, it is conceivable that impedance variations in an output buffer and impedance variations in an input buffer are adjusted by trimming. In adjustment by trimming, it is desired to reduce trimming errors.

Accordingly, in the present embodiment, impedances of the variable resistor elements 11 and 21a are adjusted on the basis of a comparison result between the reference voltage Vref generated by coupling the constant current source Ibgr to the external terminal 20B and the output voltage V21 of the replica circuit 21. This makes it possible to adjust an output impedance of the output driver 10 while avoiding an influence of a contact resistance in the external terminal 20B. This consequently makes it possible to reduce trimming errors, as compared with a case where a constant voltage source is used.

In addition, in the present embodiment, impedances of the variable resistor elements 11 and 21a are adjusted on the basis of a comparison result, by the comparator 24, between the reference voltage Vref and the output voltage of the replica circuit 21. The reference voltage Vres is generated by flowing, into the reference resistor element 28, of a current from the constant current source Ibgr coupled to the external terminal 20B. This makes it possible to adjust the output impedance of the output driver 10 while avoiding the influence of the contact resistance in the external terminal 20B. This consequently makes it possible to reduce trimming errors, as compared with a case where a constant voltage source is used.

In addition, in the present embodiment, the impedances of the variable resistor elements 11 and 21a are adjusted on the basis of a comparison result, by the comparator 24, between the output voltage V21 of the replica circuit 21 and the reference voltage Vref. The output voltage V21 of the replica circuit 21 is generated by flowing, into the replica circuit 21, of the current from the constant current source Itester coupled to the external terminal 20A. This makes it possible to adjust the output impedance of the output driver 10 while avoiding an influence of a contact resistance in the external terminal 20A. This consequently makes it possible to reduce trimming errors, as compared with a case where a constant voltage source is used.

In addition, in the present embodiment, the impedances of the variable resistor elements 11 and 21a are adjusted on the basis of respective comparison results of the voltage (the output voltage V21) of the output line L1 and the voltage (the reference voltage Vref) of the output line L2 obtained before and after interchange of input points to the comparator 24 by the selector 25a. This makes it possible to adjust the output impedance of the output driver 10 while avoiding the influence of the offset of the comparator 24. This consequently makes it possible to reduce trimming errors, as compared with a case where a constant voltage source is used.

### 2. Modification Examples of First Embodiment

Description is given below of modification examples of the transmitter 1 according to the above-described embodiment.

### Modification Example A

FIG. 6 illustrates a schematic configuration example of the transmitter 1 according to the present modification example. The transmitter 1 according to the present modification example includes the plurality of output drivers 10 and the trimming circuit 20. In the present modification example, the trimming circuit 20 corresponds to the trimming circuit 20 according to the above-described embodiment further including a reference resistor 22 and a selector 25b.

FIG. 7 illustrates an example of a circuit configuration of the trimming circuit 20 according to the present modification example. It is to be noted that the trimming circuit 20 is not limited to the circuit configuration illustrated in FIG. 7. The trimming circuit 20 includes, for example, the replica circuit 21, the reference resistor 22, the control logic 23, the comparator 24, the selectors 25a and 25b, the memory 27, and the reference resistor element 28.

In the present modification example, the control logic 23 controls the replica circuit 21, the reference resistor 22, and the selectors 25a and 25b to thereby derive the impedance code Code for adjusting the output impedance of the replica circuit 21.

The selector 25a has two input terminals and two output terminals. One of the input terminals of the selector 25a, and an output terminal of the selector 25b are electrically coupled to each other via an output line L4. The output line L4 is electrically coupled to the one of the input terminal of the selector 25a and the output terminal of the selector 25b. The other input terminal of the selector 25a and the external terminal 20B are electrically coupled to each other via the output line L2. The two output terminals of the selector 25a are coupled to the two input terminals of the comparator 24.

The selector 25b has two input terminals and one output terminals. The selector 25b interchanges coupling relations between the two input terminals of the selector 25b and the one output terminal of the selector 25b by control by the control logic 23. The selector 25b couples one of the output line L1 and a output line L3, and the output line L4 to each other. One of the input terminals of the selector 25b, and the coupling point P5 of the replica circuit 21 are electrically coupled to each other via the output line L1. The other input terminal of the selector 25b and the external terminal 20A are electrically coupled to each other via the output line L3. The output line L3 is electrically coupled to the external terminal 20A and the other input terminal of the selector 25b.

For example, as illustrated in FIG. 7, the reference resistor 22 is a circuit in which the transistor 22a and the variable resistor element 22b coupled to each other in series are inserted between the output line L4 and a fixed voltage line VTERM. The output line L4 may be electrically coupled to the variable resistor element 22b via the transistor 22a. The control logic 23 adjusts resistance of the reference resistor 22. The comparator 24 compares a voltage (V21 or V20A) of the output line L4 with the voltage (Vref) of the output line L2, and outputs, to the control logic 23, a signal corresponding to the voltage ΔV1 (=V21−Vref, or V20A−Vref) of a difference between these voltages.

### [Impedance Adjustment]

Next, description is given of output impedance adjustment in the transmitter 1 according to the present modification example. FIG. 8 illustrates an example of an output impedance adjustment procedure in the transmitter 1 according to the present modification example.

First, the control logic 23 searches for an impedance code Code3 that causes a combined resistor of the variable resistor element 22b and the transistor 22a of the reference resistor 22 to become Zo (step S201). Specifically, first, the user couples the constant current source Itester that supplies a constant current to the external terminal 20A, and couples the constant current source Ibgr that supplies a constant current to the external terminal 20B. Next, the control logic 23 outputs, to the selector 25b, a signal that causes the output line L3 and the output line L4 to be coupled to each other. This causes the selector 25b to electrically couple the output line L3 and the output line L4 to each other and electrically separate the output line L1 and the output line L4 from each other. Subsequently, the control logic 23 outputs an on signal to the transistor 22a of the reference resistor 22, and inputs an initial value of the impedance code Code3 to the variable resistor element 22b of the reference resistor 22. This turns on the transistor 22a of the reference resistor 22 to set a resistance value R22b of the variable resistor element 22b of the reference resistor 22 to a resistance value R1 corresponding to the initial value of the impedance code Code3. Furthermore, a predetermined constant current is supplied from the constant current source Itester coupled to the external terminal 20A to the reference resistor 22, a predetermined constant current is supplied from constant current source Ibgr coupled to the external terminal 20B to the reference resistor element 28. As a result, a voltage V22 (=the voltage V20A of the external terminal 20A) of the reference resistor 22 becomes a predetermined voltage value (Itester×(R1+Rtr1)), and the voltage V20B of the external terminal 20B becomes a predetermined voltage value (Ibgr×Rref=the reference voltage Vref). It is to be noted that Rtr1 is a resistance value between a source and a drain of the transistor 22a in an on state of the reference resistor 22. The voltage (=the voltage V22) of the output line L4 and the voltage (=the reference voltage Vref) of the output line L2 are inputted to the comparator 24, and a signal corresponding to the voltage ΔV1 (=V22−Vref) of a difference between these voltages is inputted to the control logic 23 from the comparator 24. The control logic 23 sets the impedance code Code3 to a value that causes the voltage ΔV1 to approach zero, and outputs the value after such setting to the variable resistor element 22b of the reference resistor 22. The control logic 23 resets the impedance code Code until the voltage ΔV1 becomes zero (or a value close to zero and within an allowable range). Consequently, when the voltage ΔV1 becomes zero (or the value close to zero and within the allowable range), the control logic 23 stores the set value at that time as the impedance code Code3 in the memory 27. Thus, the control logic 23 searches for the impedance code Code3 that causes the combined resistor of the variable resistor element 22b and the transistor 22a of the reference resistor 22 to become Zo.

Next, the control logic 23 interchanges input to the comparator 24 (step S202). Specifically, the control logic 23 inputs a control signal to the selector 25 to thereby interchange the coupling relations between the two input terminals of the selector 25 and the two output terminals of the selector 25 (i.e., the two input terminals of the comparator 24).

The control logic 23 then searches for an impedance code Code4 that causes the combined resistor of the variable resistor element 22b and the transistor 22a of the reference resistor 22 to become Zo, by a method similar to the step S201 (step S203). Thereafter, the control logic 23 derives, on the basis of the impedance codes Code3 and Code4, the impedance code Code in which an influence of an offset of the comparator 24 is reduced (step S204). The control logic 23 derives an impedance code Code5 in which the influence of the offset of the comparator 24 is reduced, with use of the following expression, for example.

Code5=Code3−(Code3−Code4)/2

The control logic 23 then searches for an impedance code Code6 that causes the combined resistor of the variable resistor element 21a and the transistor 21b of the replica circuit 21 to become Zo (step S205). Specifically, first, the control logic 23 outputs, to the selector 25b, a signal that causes the output line L1 and the output line L4 to be coupled to each other. This causes the selector 25b to electrically couple the output line L1 and the output line L4 to each other and electrically separate the output line L3 and the output line L4 from each other. Subsequently, the control logic 23 outputs an off signal to the transistor 22a of the reference resistor 22. This turns off the transistor 22a of the reference resistor 22 to electrically separate the variable resistor element 22b of the reference resistor 22 from the output line L4. Subsequently, the control logic 23 outputs an on signal to the two transistors 21b of the replica circuit 21, and inputs, to the two variable resistor element 21a of the replica circuit 21, the impedance code Code5 in which the influence of the offset of the comparator 24 is reduced. This turns on the two transistors 21b of the replica circuit 21. In addition, the resistance value R21a of the variable resistor element 21a on the fixed voltage line VIO side of the replica circuit 21 is set to a resistance value R2 corresponding to the impedance code Code5, and the resistance value R21a of the variable resistor element 21a on the fixed voltage line VSS side of the replica circuit 21 is set to a resistance value R3 corresponding to the impedance code Code5. As a result, the output voltage V21 of the replica circuit 21 (=the voltage V20A of the external terminal 20A) becomes a predetermined voltage value ((VIO−VSS)×(R3+Rtr3)/(R2+R3+Rtr2+Rtr3)), and the voltage V20B of the external terminal 20B becomes a predetermined voltage value (Ibgr×Rref=the reference voltage Vref). It is to be noted that Rtr2 is a resistance value between the source and the drain of the transistor 21b in the on state on the fixed voltage line VSS side of the replica circuit 21. Rtr3 is a resistance value between the source and the drain of the transistor 21b in the on state on the fixed voltage line VSS side of the replica circuit 21. The voltage of the output line L4 (=the output voltage V21) and the voltage of the output line L2 (=the reference voltage Vref) are inputted to the comparator 24, and a signal corresponding to the voltage ΔV1 (=V21−Vref) of a difference between these voltages is inputted from the comparator 24 to the control logic 23. The control logic 23 sets the impedance code Code6 to a value that causes the voltage ΔV1 to approach zero, and outputs the value after such setting to the two variable resistor element 21a of the replica circuit 21. The control logic 23 resets the impedance code Code6 until the voltage ΔV1 becomes zero (or a value close to zero and within an allowable range). Consequently, when the voltage ΔV1 becomes zero (or the value close to zero and within the allowable range), the control logic 23 stores the set value at that time as the impedance code Code6 in the memory 27. Thus, the control logic 23 searches for the impedance code Code6 that causes the combined resistor of the variable resistor element 21a and the transistor 21b of the replica circuit 21 to become Zo.

Next, the control logic 23 interchanges input to the comparator 24 (step S206). Specifically, the control logic 23 inputs a control signal to the selector 25 to thereby interchange the coupling relations between the two input terminals of the selector 25 and the two output terminals of the selector 25 (i.e., the two input terminals of the comparator 24).

The control logic 23 then searches for an impedance code Code7 that causes the combined resistor of the variable resistor element 21a and the transistor 21b of the replica circuit 21 to become Zo, by a method similar to the step S205 (step S207). Thereafter, the control logic 23 derives, on the basis of the impedance codes Code6 and Code7, the impedance code Code in which the influence of the offset of the comparator 24 is reduced (step S208). The control logic 23 derives the impedance code Code in which the influence of the offset of the comparator 24 is reduced, with use of the following expression, for example.

Code=Code6−(Code6−Code7)/2

The control logic 23 stores the derived impedance code Code in the memory 27. The control logic 23 outputs the impedance code Code read from the memory 27 to the output driver 10 to thereby control (adjust) the output impedance of the output driver 10 (e.g., the variable resistor element 11).

### [Effects]

Next, description is given of effects of the transmitter 1 according to the present modification example.

In the present modification example, the impedances of the variable resistor elements 11 and 21a are adjusted on the basis of a comparison result between the reference voltage Vref generated by coupling the constant current source Ibgr to the external terminal 20B and the voltage V22 of the reference resistor 22, and a comparison result between the reference voltage Vref generated by coupling the constant current source Ibgr to the external terminal 20B and the output voltage V21 of the replica circuit 21. This makes it possible to adjust the output impedance of the output driver 10 while avoiding the influence of the contact resistance in the external terminal 20B. This consequently makes it possible to reduce trimming errors, as compared with a case where a constant voltage source is used.

In addition, in the present modification example, the impedances of variable resistor elements 11 and 21a are adjusted on the basis of a comparison result, by the comparator 24, between the reference voltage Vref, which is generated by flowing, into the reference resistor element 28, of a current from the constant current source Ibgr coupled to the external terminal 20B, and the voltage V22, which is generated by flowing, into the reference resistor 22, of a current from the constant current source Itester coupled to the external terminal 20A, and a comparison result, by the comparator 24, between the reference voltage Vref, which is generated by flowing, into the reference resistor element 28, of a current from the constant current source Ibgr coupled to the external terminal 20B, and the output voltage V21 of the replica circuit 21. This makes it possible to adjust the output impedance of the output driver 10 while avoiding the influence of the contact resistance in the external terminal 20B. This consequently makes it possible to reduce trimming errors, as compared with a case where a constant voltage source is used.

In addition, in the present modification example, the impedances of the variable resistor elements 11 and 21a are adjusted on the basis of respective comparison results of one of the voltage (the output voltage V21) of the output line L1 and the voltage (the voltage V22) of the output line L3 (voltage V22), and the voltage (the reference voltage Vref) of output line L2 obtained before and after interchanges of input points to the comparator 24 by the selector 25a. This makes it possible to adjust the output impedance of the output driver 10 while avoiding the influence of the offset of the comparator 24. This consequently makes it possible to reduce trimming errors, as compared with a case where a constant voltage source is used.

### Modification Example B

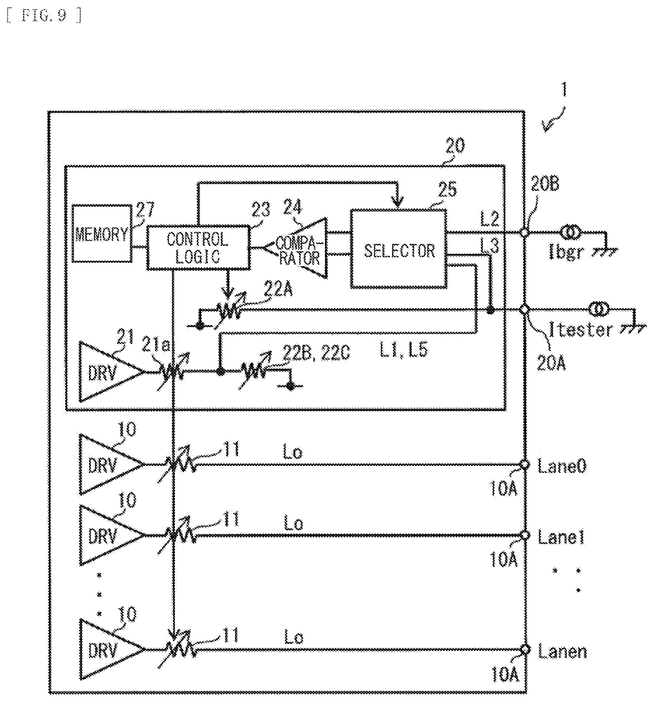

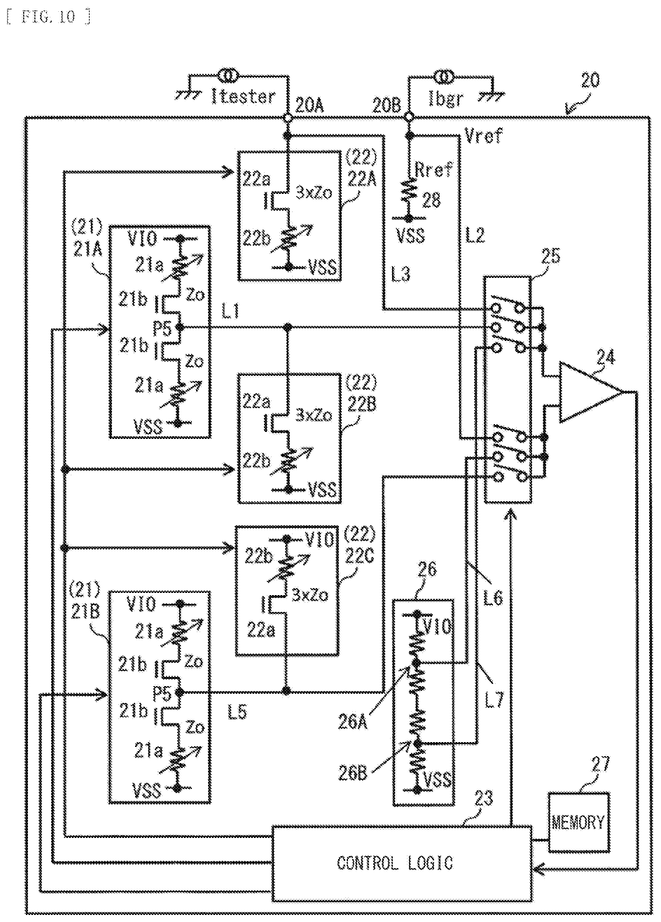

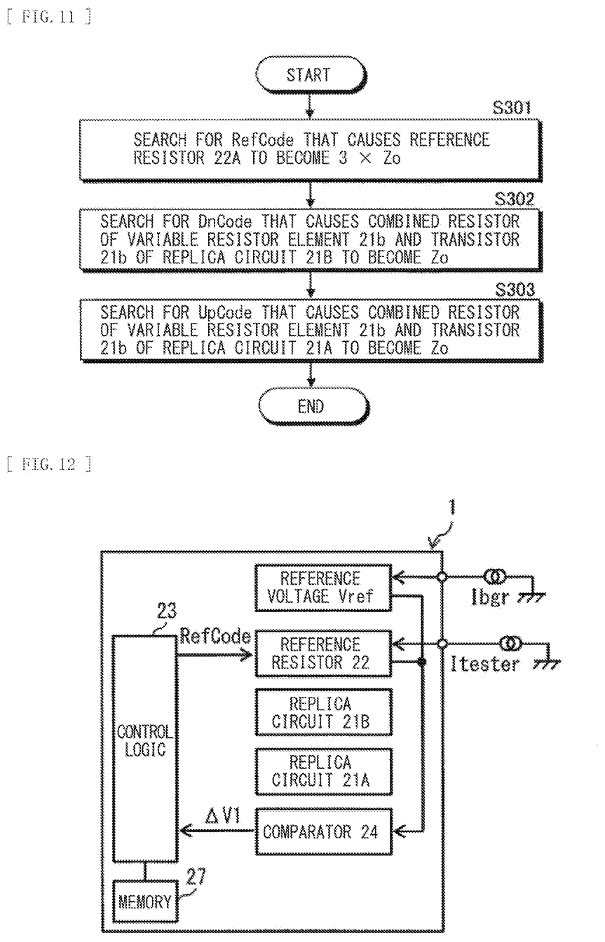

FIG. 9 illustrates a schematic configuration example of the transmitter 1 according to the present modification example. The transmitter 1 according to the present modification example includes the plurality of the output drivers 10, and the trimming circuit 20. Trimming circuit 20 according to the present modification example corresponds to the trimming circuit 20 according to the above-described embodiment that includes a selector 25 instead of the selector 25a and further includes three reference resistors 22A, 22B, and 22C.

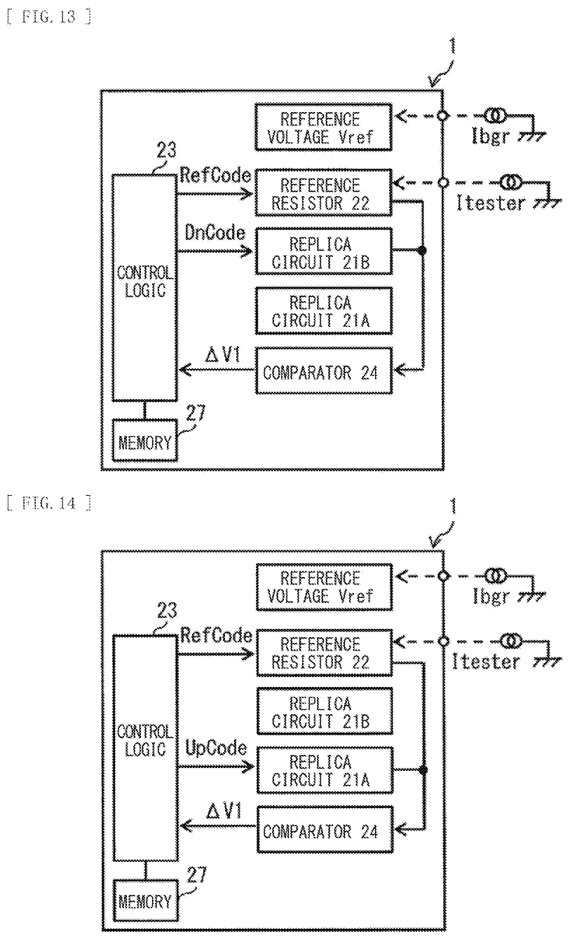

FIG. 10 illustrates an example of a circuit configuration of the trimming circuit 20 according to the present modification example. It is to be noted that the trimming circuit 20 is not limited to the circuit configuration illustrated in FIG. 10. The trimming circuit 20 includes, for example, two replica circuits 21 (21A and 21B), three reference resistors 22 (22A, 22B, and 22C), the control logic 23, the comparator 24, the selector 25, a voltage generation circuit 26, the memory 27, and the reference resistor element 28.

The replica circuits 21A and 21B each have the same configuration as the output driver 10. The replica circuits 21A and 21B each have, for example, any of the circuit configurations illustrated in FIG. 3A, FIG. 3B, FIG. 3C, or FIG. 3D described above.

The control logic 23 adjusts output impedances of the two replica circuits 21 (21A and 21B). The control logic 23 controls the replica circuit 21A and the selector 25 to thereby derive the impedance code Code6 for adjusting the output impedance of the replica circuit 21A. The control logic 23 further controls the replica circuit 21B and the selector 25 to thereby derive the impedance code Code7 for adjusting the output impedance of the replica circuit 21B. The control logic 23 stores the derived impedance codes Code6 and Code7 in the memory 27. The control logic 23 further adjusts the output impedance of the output driver 10. The control logic 23 adjusts the output impedance of the output driver 10 with use of the impedance codes Code6 and Code7 read from the memory 27.

The selector 25 has, for example, six input terminals and two output terminals. The selector 25 is configured to allow three input terminals (input terminals X1) of the six input terminals to be coupled to one (an output terminal Y1) of the output terminals. Further, the selector 25 is configured to allow three input terminals (input terminals X2) different from the three input terminals (the input terminals X1) of the six input terminals to be coupled to the other output terminal (an output terminal Y2). The selector 25 interchanges coupling relations between the three input terminals (the input terminal X1) and the one output terminal (the output terminal Y1) and interchanges coupling relations between the three input terminals (the input terminals X2) and the other output terminal (the output terminal Y2) by control by the control logic 23. The selector 25 selects one of the output line L1, the output line L3, and an output line L7, and one of the output line L2, the output line L5, and an output line L6. The comparator 24 outputs, to the control logic 23, a difference between two signals inputted via the selector 25. The comparator 24 compares the voltage of one of the output line L1, the output line L3, and the output line L7 with the voltage of one of the output line L2, the output line L5, and the output line L6, and outputs a signal corresponding to the voltage ΔV1 of a difference between these voltages to the control logic 23.

One of the three input terminals X1 and the external terminal 20A are electrically coupled to each other via the output line L3. The output line L3 is electrically coupled to one of the three input terminals X1 (the input terminals X1) and the external terminal 20A. One of the three input terminals (the input terminals X1) and the coupling point P5 of the replica circuit 21A are electrically coupled to each other via the output line L1. The output line L1 is electrically coupled to one of the three input terminals (the input terminals X1) and the coupling point P5 of the replica circuit 21A. One of the three input terminals (the input terminals X1) and a terminal 26A on a high-voltage side of the voltage generation circuit 26 are electrically coupled to each other via the output line L6. One of the three input terminals (the input terminals X2) and the external terminal 20B are electrically coupled to each other via the output line L2. The output line L2 is electrically coupled to one of the three input terminals (the input terminals X2) and the external terminal 20B. One of the three input terminals (the input terminals X2) and a terminal 26B on a low-voltage side of the voltage generation circuit 26 are electrically coupled to each other via the output line L7. One of the three input terminals (the input terminals X2) and the coupling point P5 of the replica circuit 21B are electrically coupled to each other via the output line L5. The output line L5 is electrically coupled to one of the three input terminals (the input terminals X2) and the coupling point P5 of the replica circuit 21B. The two output terminals of the selector 25 are coupled to the two input terminal of the comparator 24.

For example, as illustrated in FIG. 10, the reference resistor 22A is a circuit in which the transistor 22a and the variable resistor element 22b coupled to each other in series are inserted between the external terminal 20A and the fixed voltage line VSS. The variable resistor 22b of the reference resistor 22A may be electrically coupled to the output line L3 via the transistor 22a. For example, as illustrated in FIG. 10, the reference resistor 22B is a circuit in which the transistor 22a and the variable resistor element 22b coupled to each other in series are inserted between the output line L1 and the fixed voltage line VSS. The variable resistor element 22b of the reference resistor 22B may be electrically coupled to the output line L1 via the transistor 22a. For example, as illustrated in FIG. 10, the reference resistor 22C is a circuit in which the transistor 22a and the variable resistor element 22b coupled to each other in series are inserted between the output line L5 and the fixed voltage line VIO. The variable resistor 22b of the reference resistor 22C may be electrically coupled to the output line L5 via the transistor 22a.

The voltage generation circuit 26 has a circuit configuration that is able to divide a voltage (VIO−VSS) into ¾ at the terminal 26A on the high-voltage side described above and divide the voltage (VIO−VSS) into ¼ at the terminal 26B on the low-voltage side described above. A voltage V26A of the terminal 26A is (VIO−VSS)×¾. A voltage V26B of the terminal 26B is (VIO−VSS)×¼. For example, as illustrated in FIG. 10, the voltage generation circuit 26 has a circuit configuration in which four resistors equivalent to each other are coupled to one another in series between the fixed voltage line VIO and the fixed voltage line VSS. At this time, resistance values of the respective resistors in the voltage generation circuit 26 are equal to one another, and is Zo, for example. It is to be noted that the resistance values of the respective resistors in the voltage generation circuit 26 are not limited to Zo, and may be 100×Zo, for example.

### [Impedance Adjustment]

Next, description is given of output impedance adjustment in the transmitter 1 according to the present modification example. FIG. 11 illustrates an example of an output impedance adjustment procedure in the transmitter 1 according to the present modification example.

First, the control logic 23 searches for a reference impedance code RefCode that causes the reference resistor 22A to become 3×Zo (S301 in FIG. 12). Specifically, first, the user couples a constant current source to the external terminal 20A and couples a constant current source to the external terminal 20B. Subsequently, the control logic 23 outputs an on signal to the transistor 22a of the reference resistor 22A, and inputs an initial value of the reference impedance code RefCode to the variable resistor element 22b of the reference resistor 22A. This turns on the transistor 22a of the reference resistor 22A to set the resistance value R22b of the variable resistor element 22b of the reference resistor 22A to a resistance value Rini1 corresponding to the initial value of the reference impedance code RefCode. Furthermore, a current Itester from the constant current source coupled to the external terminal 20A is supplied to the reference resistor 22A, and a current Ibgr from the constant current source coupled to the external terminal 20B is supplied to the reference resistor element 28. As a result, the voltage V22A of the reference resistor 22A (=the voltage V20A of the external terminal 20A) becomes a predetermined voltage value (Itester×(Rini1+Rtr1)), and the voltage V20B of the external terminal 20B becomes a predetermined voltage value (Ibgr×Rref=the reference voltage Vref). It is to be noted Rtr1 is a resistance value between the source and the drain of the transistor 22a in the on state of the reference resistor 22. Rref may take any value. For example, in a case of Itester=2 mA and Zo=50Ω, the voltage V20A of the external terminal 20A is 300 mV; therefore, it is sufficient to set the current Ibgr and the resistance value Rref of the reference resistor element 28 that cause the voltage V20A to become 300 mV. Thereafter, the control logic 23 outputs, to the selector 25, a signal for selecting the input terminal linked to the output line L3 and the input terminal linked to the output line L2. This causes the selector 25 to select the input terminal linked to the output line L3 and the input terminal linked to the output line L2. As a result, the voltage (=V22A) of the output line L3 and the voltage (=the reference voltage Vref) of the output line L2 are inputted to the comparator 24, and a signal corresponding to the voltage ΔV1 (=V22A−Vref) of a difference between these voltages is inputted from the comparator 24 to the control logic 23. The control logic 23 sets the reference impedance code RefCode to a value that causes the voltage ΔV1 to approach zero (or a value close to zero and within an allowable range), and outputs the value after such setting to the variable resistor element 22b of the reference resistor 22A. The control logic 23 resets the reference impedance code RefCode until the voltage ΔV1 becomes zero (or a value close to zero and within the allowable range). Consequently, when the voltage ΔV1 becomes zero (or the value close to zero and within the allowable range), the control logic 23 stores the set value at that time as the reference impedance code RefCode in the memory 27. Thus, the control logic 23 searches for the reference impedance code RefCode that causes the reference resistor 22A to become 3×Zo.

Next, the control logic 23 searches for a pull-down impedance code DnCode that causes the combined resistor of the variable resistor element 21a and the transistor 21b of the replica circuit 21B to become Zo (S302 in FIG. 13). Specifically, first, the control logic 23 outputs an on signal to the transistor 21b on the fixed voltage line VSS side of the replica circuit 21B, and inputs an initial value of the pull-down impedance code DnCode to the variable resistor element 21a on the fixed voltage line VSS side of the replica circuit 21B. This turns on the transistor 21b on the fixed voltage line VSS side of the replica circuit 21B to set the resistance value of the variable resistor element 21a on the fixed voltage line VSS side of the replica circuit 21B to a resistance value Rini2 corresponding to the initial value of the pull-down impedance code DnCode. Furthermore, the control logic 23 outputs an on signal to the transistor 22a of the reference resistor 22C, and inputs the reference impedance code RefCode read from the memory 27 to the variable resistor element 22b of the reference resistor 22C. This turns on the transistor 22a of the reference resistor 22C to set the resistance value of the variable resistor element 22b of the reference resistor 22C to a resistance value corresponding to the reference impedance code RefCode read from the memory 27. Thereafter, the control logic 23 outputs, to the selector 25, a signal for selecting the input terminal linked to the output line L5 and the input terminal linked to the output line L7. This causes the selector 25 to select the input terminal linked to the output line L5 and the input terminal linked to the output line L7. As a result, the voltage (=V21B) of the output line L5 and the voltage (=(VIO−VSS)×¼) of the output line L7 are inputted to the comparator 24, and a signal corresponding to the voltage ΔV1 (=V21B−(VIO−VSS)×¼) of a difference between these voltages is inputted from the comparator 24 to the control logic 23. The control logic 23 sets the pull-down impedance code DnCode to a value that causes the voltage ΔV1 to approach zero, and outputs the value after such setting to the variable resistor element 21a of the replica circuit 21B. The control logic 23 resets the pull-down impedance code DnCode until the voltage ΔV1 becomes zero (or a value close to zero and within an allowable range). Consequently, when the voltage ΔV1 becomes zero (or the value close to zero and within the allowable range), the control logic 23 stores the set value at that time as the pull-down impedance code DnCode in the memory 27. Thus, the control logic 23 searches for the pull-down impedance code DnCode that causes the combined resistor of the variable resistor element 21a and the transistor 21b of the replica circuit 21B to become Zo.

Next, the control logic 23 searches for a pull-up impedance code UpCode that causes the combined resistor of the variable resistor element 21a and the transistor 21b of the replica circuit 21A to become Zo (S303 in FIG. 14). Specifically, first, the control logic 23 outputs an on signal to the transistor 21b on the fixed voltage line VIO side of the replica circuit 21A, and inputs an initial value of the pull-up impedance code DnCode to the variable resistor element 21a on the fixed voltage line VIO side of the replica circuit 21A. This turns on the transistor 21b on the fixed voltage line VIO side of the replica circuit 21B to set the resistance value of the variable resistor element 21a on the fixed voltage line IO of the replica circuit 21Bt to a resistance value Rini3 corresponding to the initial value of the pull-up impedance code UpCode. Furthermore, the control logic 23 outputs an on signal to the transistor 22a of the reference resistor 22B, and inputs the reference impedance code RefCode read from the memory 27 to the variable resistor element 22b of the reference resistor 22B. This turns on the transistor 22a of the reference resistor 22B to set the resistance value of the variable resistor element 22b of the reference resistor 22B to a resistance value corresponding to the reference impedance code RefCode read from the memory 27. Thereafter, the control logic 23 outputs, to the selector 25, a signal for selecting the input terminal linked to the output line L1 and the input terminal linked to the output line L6. This causes the selector 25 to select the input terminal linked to the output line L1 and the input terminal linked to the output line L6. As a result, the voltage (=V21A) of the output line L1 and the voltage (=(VIO−VSS)×¾) of the output line L6 are inputted to the comparator 24, and a signal corresponding to the voltage ΔV1 (=V21A−(VIO−VSS)×¾) of a difference between these voltages is inputted from the comparator 24 to the control logic 23. The control logic 23 sets the pull-up impedance code UpCode to a value that causes the voltage ΔV1 to approach zero, and outputs the value after such setting to the variable resistor element 21a of the replica circuit 21A. The control logic 23 resets the pull-up impedance code UpCode until the voltage ΔV1 becomes zero (or a value close to zero and within an allowable range). Consequently, when the voltage ΔV1 becomes zero (or the value close to zero and within the allowable range), the control logic 23 stores the set value at that time as the pull-up impedance code UpCode in the memory 27. Thus, the control logic 23 searches for the pull-up impedance code UpCode that causes the combined resistor of the variable resistor element 21a and the transistor 21b of the replica circuit 21A to become Zo.

The control logic 23 outputs the pull-down impedance code DnCode read from the memory 27 to the output driver 10 to thereby control (adjust) the output impedance of the output driver 10 (e.g., the variable resistor element 11). In addition, the control logic 23 outputs the pull-up impedance code UpCode read from the memory 27 to the output driver 10 to thereby control (adjust) the output impedance of the output driver 10 (e.g., the variable resistor element 11). It is to be noted that in a case where an offset voltage VOS is present in the comparator 24, interchanging input of the comparator 24 makes it possible to reduce an influence of the offset voltage VOS.

### [Effects]

Next, description is given of effects of the transmitter 1 according to the present modification example.

In the present modification example, the impedances of the variable resistor elements 11 and 21a are adjusted on the basis of a comparison result (a first comparison result) between the reference voltage Vref, which is generated by coupling the constant current source Ibgr to the external terminal 20B, and the voltage V22A, which is generated by flowing, into the reference resistor 22A. of a current generated by coupling the external terminal 20A to the constant current source Itester, and a comparison result (a second comparison result) between the output voltage V21A of the replica circuit 21A in a state in which the variable resistor element 22b of the reference resistor 22B is coupled to the output line L1, and the voltage V26A of the output line L6, and a comparison result (a third comparison result) between the output voltage V21B of the replica circuit 21B in a state in which the variable resistor element 22b of the reference resistor 22C is coupled to the output line L5, and the voltage V26B of the output line L7. This makes it possible to adjust the output impedance of the output driver while avoiding an influence of contact resistances in the external terminals 20A and 20B. This consequently makes it possible to reduce trimming errors, as compared with a case where a constant voltage source is used.

In addition, in the present modification example, the impedances of the variable resistor elements 11 and 21a are adjusted on the basis of a comparison result, by the comparator 24, between the reference voltage Vref, which is generated by flowing, into the reference resistor element 28, of a current from the constant current source Ibgr coupled to the external terminal 20B, and the voltage V22A, which is generated by flowing, into the reference resistor 22A, of a current generated by coupling the constant current source Itester to the external terminal 20A, the above-described second comparison result, and the above-described third comparison result. This makes it possible to adjust the output impedance of the output driver 10 while avoiding the influence of the contact resistances in the external terminals 20A and 20B. This consequently makes it possible to reduce trimming errors, as compared with a case where a constant voltage source is used.

It is to be noted that, in the present modification example, for example, as illustrated in FIG. 15, the external terminal 20B may be omitted, and a constant current source that supplies the current Ibgr may be incorporated in the transmitter 1 according to the present modification example. Even in such a case, it is possible to adjust the output impedance of the output driver 10 while avoiding the influence of the contact resistance in the external terminal 20B. This consequently makes it possible to reduce trimming errors, as compared with a case where a constant voltage source is used.

### Modification Example C

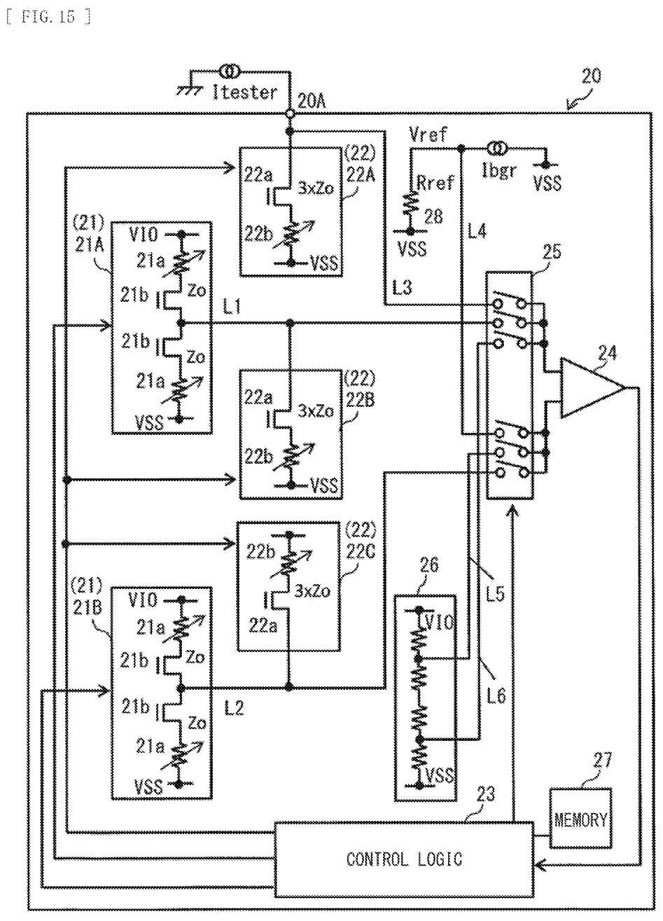

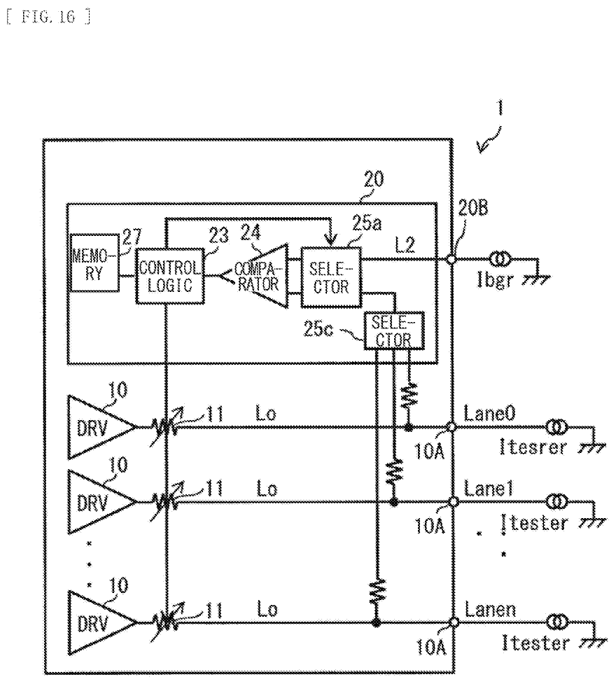

FIG. 16 illustrates an modification example of a schematic configuration of the transmitter 1 according to the present modification example. The transmitter 1 according to the present modification example corresponds to that in which the replica circuit 21 and the external terminal 20A are omitted and a selector 25c is further included. One end of the output line Lo is coupled to an output end of each of the output drivers 10 and another end of the output line Lo is coupled to the external terminal 10A.

The selector 25c has a plurality of input terminals and one output terminal. The respective input terminals of the selector 25c are electrically coupled to respective output lines Lo, and a resistor element is inserted in each of wiring lines that couples the respective input terminals of the selector 25c and the respective output lines Lo. The selector 25c selects one of a plurality of output lines Lo.

The selector 25a has two input terminals and two output terminals. The selector 25a interchanges coupling relations between the two input terminals of the selector 25a and the two output terminals of the selector 25a (i.e., the two input terminals of the comparator 24) by control by the control logic 23. The comparator 24 outputs, to the control logic 23, a difference between two signals inputted via the selector 25a.

One of the input terminals of the selector 25a and the output terminal of the selector 25c are electrically coupled to each other. The other input terminal of the selector 25a and the external terminal 20B are electrically coupled to each other via the output line L2. The two output terminals of the selector 25a are coupled to the two input terminals of the comparator 24. In a case where the output impedance of the output driver 10 is adjusted, the external terminal 10A is coupled to the constant current source Itester that supplies a constant current. In the selector 25a, coupling relations between the two input terminals of the selector 25a and the two output terminals of the selector 25a (i.e., the two input terminals of the comparator 24) are interchanged by control by the control logic 23.

### [Impedance Adjustment]

Next, description is given of output impedance adjustment in the transmitter 1 according to the present modification example.

The control logic 23 searches for the impedance code Code1 that causes the variable resistor element 11a of the output driver 10 to become Zo. Specifically, first, the user couples the constant current source Itester that supplies a constant current to each of the external terminals 10A, and couples the constant current source Ibgr that supplies a constant current to the external terminal 20B. Next, the control logic 23 outputs, to the selector 25c, a signal for selecting one input terminal of the plurality of input terminals of the selector 25c. This causes the selector 25c to select the one input terminal of the plurality of input terminals. Subsequently, the control logic 23 outputs an on signal to the transistor 11b on the fixed voltage line VSS side of each of the output drivers 10, and inputs the initial value of the impedance code Code1 to the variable resistor element 11a on the fixed voltage line VSS side of each of the output drivers 10. This turns on the transistor 11b on the fixed voltage line VSS side of each of the output drivers 10 to set the resistance value R11a of the variable resistor element 11a on the fixed voltage line VSS side of each of the output drivers 10 to the resistance value R0 corresponding to the initial value of the impedance code Code1. Furthermore, a predetermined constant current from the constant current source Itester coupled to each external terminal 10A is supplied to the variable resistor element 11a on the fixed voltage line VSS side of each of the output drivers 10, and a predetermined constant current from the constant current source Ibgr coupled to the external terminal 20B is supplied to the reference resistor element 28. As a result, the output voltage V11 of each of the output drivers 10 (=the voltage V10A of the external terminal 10A) becomes a predetermined voltage value (Itester×(R1+Rtr)), and the voltage V20B of the external terminal 20B becomes a predetermined voltage value (Ibgr×Rref=the reference voltage Vref). It is to be noted that Rtr is a resistance value between the source and the drain of the transistor 11b in the on state on the fixed voltage line VSS side of each of the output drivers 10. The voltage (=the output voltage V11) of the output line Lo and the voltage (=the reference voltage Vref) of the output line L2 are inputted to the comparator 24, and a signal corresponding to the voltage ΔV1 (=V11−Vref) of a difference between these voltages is inputted from the comparator 24 to the control logic 23. The control logic 23 sets the impedance code Code1 to a value that causes the voltage ΔV1 to approach zero, and outputs the value after such setting to the variable resistor element 11a on the fixed voltage line VSS side of each of the output drivers 10. The control logic 23 resets the impedance code Code1 until the voltage ΔV1 becomes zero (or a value close to zero and within an allowable range). Consequently, when the voltage ΔV1 becomes zero (or the value close to zero and within the allowable range), the control logic 23 stores the set value at that time as the impedance code Code1 in the memory 27. Thus, the control logic 23 searches for the impedance code Code1 that causes the variable resistor element 21a of one output driver 10 to become Zo.

Thereafter, the control logic 23 outputs, to the selector 25c, a signal for sequentially selecting one input terminal of the plurality of input terminals of the selector 25c. This causes the selector 25c to sequentially select one input terminal of the plurality of input terminals. The control logic 23 performs the above-described control to search for the impedance code Code1 for each output driver 10 that causes the variable resistor element 21a to become Zo in each of the output drivers 10.

In the present modification example, the impedance of the variable resistor element 11 is adjusted on the basis of a comparison result between the reference voltage Vref, which is generated by coupling the constant current source Ibgr to the external terminal 20B, and the voltage V10A, which is generated by coupling the constant current source Itester to the external terminal 10A. This makes it possible to adjust the output impedance of the output driver while avoiding the influence of the contact resistances in the external terminals 10A and 20B. This consequently makes it possible to reduce trimming errors, as compared with a case where a constant voltage source is used.

### Modification Example D

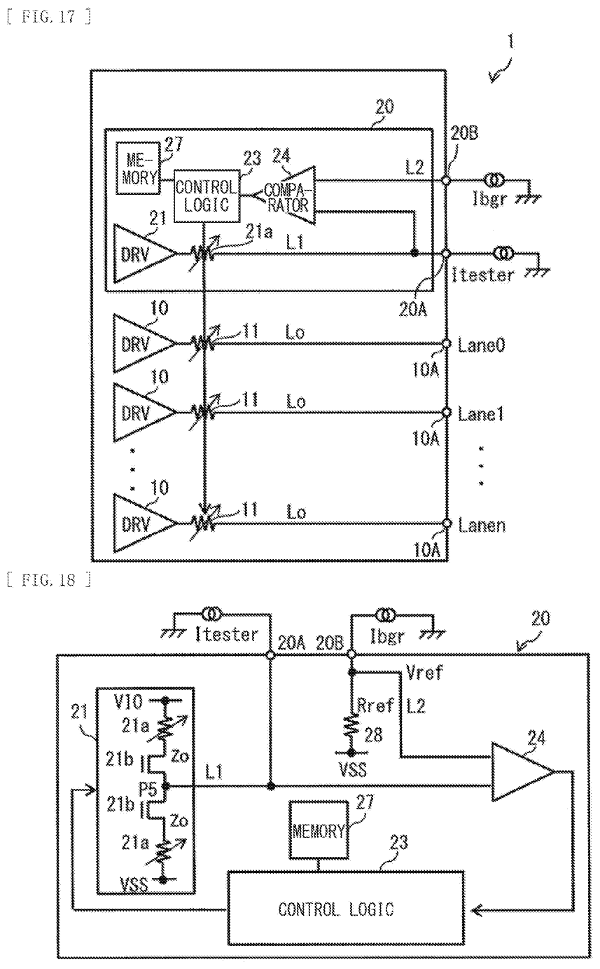

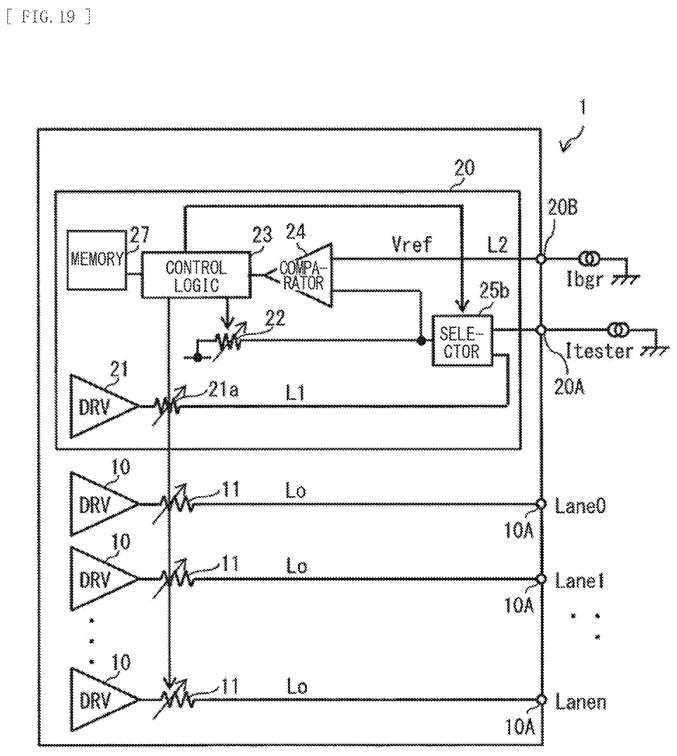

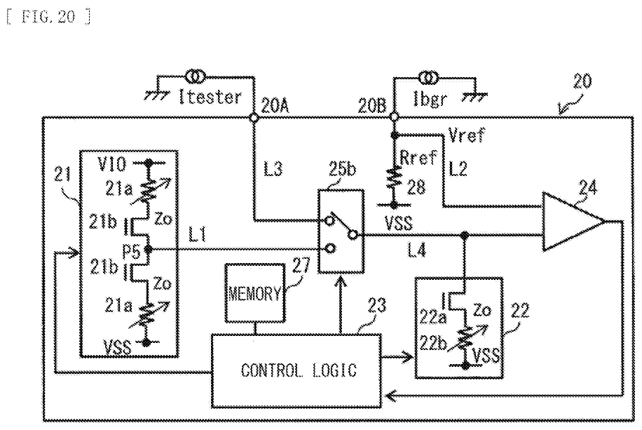

FIG. 17 illustrates an modification example of a schematic configuration of the transmitter 1 according to the present modification example. FIG. 18 illustrates an example of a circuit configuration of the trimming circuit 20 in FIG. 17. The transmitter 1 according to the present modification example corresponds to the transmitter 1 according to the above-described embodiment in which the selector 25a is omitted. In a case where an offset voltage of the comparator 24 is small, it is possible to omit the selector 25a. Thus, even in a case where the selector 25a is omitted, it is possible to adjust the output impedance of the output driver 10 while avoiding the influence of the contact resistances in the external terminals 20A and 20B. This consequently makes it possible to reduce trimming errors, as compared with a case where a constant voltage source is used.

### Modification Example E

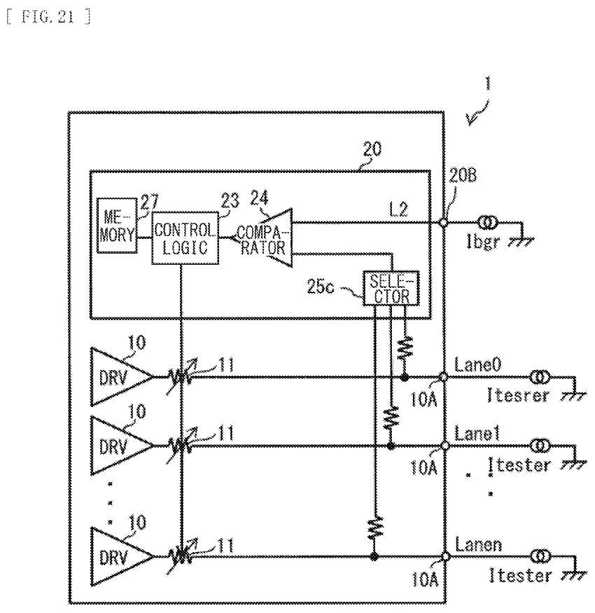

FIG. 19 illustrates an modification example of a schematic configuration of the transmitter 1 according to the present modification example. FIG. 20 illustrates an example of a circuit configuration of the trimming circuit 20 in FIG. 19. The transmitter 1 according to the present modification example corresponds to the transmitter 1 according to the above-described modification example A in which the selector 25a is omitted. In a case where the offset voltage of the comparator 24 is small, it is possible to omit the selector 25a. Thus, even in a case where the selector 25a is omitted, it is possible to adjust the output impedance of the output driver 10 while avoiding the influence of the contact resistances in the external terminals 20A and 20B. This consequently makes it possible to reduce trimming errors, as compared with a case where a constant voltage source is used.

### Modification Example F

FIG. 21 illustrates an modification example of a schematic configuration of the transmitter 1 according to the present modification example. The transmitter 1 according to the present modification example corresponds to the transmitter 1 according to the above-described modification example C in which the selector 25a is omitted. In a case where the offset voltage of the comparator 24 is small, it is possible to omit the selector 25a. Thus, even in a case where the selector 25a is omitted, it is possible to adjust the output impedance of the output driver 10 while avoiding the influence of the contact resistances in the external terminals 20A and 20B. This consequently makes it possible to reduce trimming errors, as compared with a case where a constant voltage source is used.

### 3. Second Embodiment

### [Configuration]

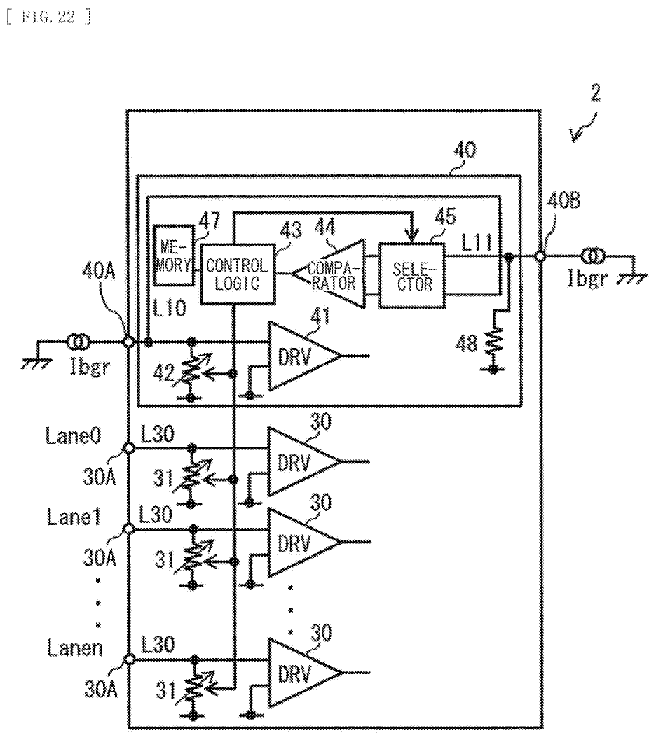

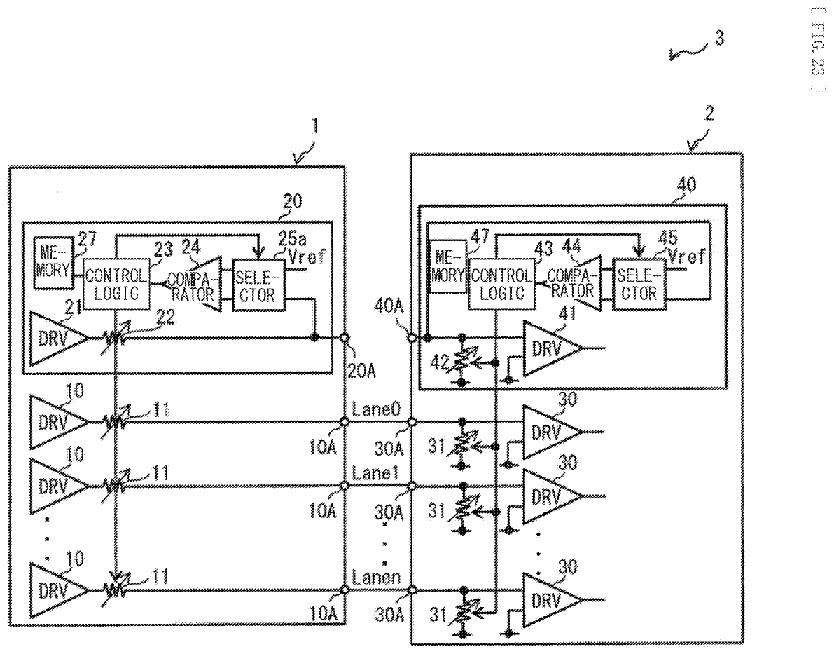

Description is given of a receiver 2 according to a second embodiment of the present disclosure. FIG. 22 illustrates a schematic configuration example of the receiver 2. The receiver 2 includes a plurality of driver circuits 30, and a trimming circuit 40. Each of the driver circuits 30 includes a variable resistor element 31. One end of an input line L30 is coupled to an input end of each of the driver circuits 30, and another end of the input line L30 is coupled to an external terminal 30A.

The trimming circuit 40 is a circuit that adjusts an input impedance of the driver circuit 30 to perform impedance matching between the driver circuit 30 and a transmission line. The trimming circuit 40 outputs the impedance code Code to the driver circuit 30 to thereby control the input impedance of the driver circuit 30.

The trimming circuit 40 includes, for example, a replica circuit 41 having the same configuration as the driver circuit 30. One end of an input line L10 is coupled to an input end of the replica circuit 41, and another end of the input line L10 is coupled to an external terminal 40A. The trimming circuit 40 further includes, for example, a control logic 43 (a control circuit), a comparator 44, a selector 45, and a memory 47. The initial value of the impedance code Code is stored in the memory 47. It is to be noted that the memory 47 may be initially in an unwritten state, and a value read from the memory 47 in the unwritten state may be used as the initial value of the impedance code Code. Even in this case, it may be considered that the initial value of the impedance code Code is stored in the memory 47. A set value of the impedance code Code derived by the control logic 43 is further stored in the memory 47. A constant current source is coupled to each of the external terminals 40A and 40B of the trimming circuit 40 on an as-needed basis.

The control logic 43 adjusts an input impedance of the replica circuit 41. The control logic 43 controls the replica circuit 41 and the selector 45 to thereby drive the impedance code Code for adjusting the input impedance of the replica circuit 41. The control logic 43 stores the derived impedance code Code in the memory 47. The control logic 43 further adjusts the input impedance of the driver circuit 30. The control logic 43 adjusts the input impedance of the driver circuit 30 with use of the impedance code Code read from the memory 47.

The selector 45 has two input terminals and two output terminals. One of the input terminals of the selector 45 and the external terminal 40A are electrically coupled to each other via the input line L10. The other input terminal of the selector 45 and the external terminal 40B are electrically coupled to each other via an input line L11. The two output terminals of the selector 45 are coupled to two input terminals of the comparator 44. In a case where the input impedance of replica circuit 41 is adjusted, the constant current source Itester that supplies a constant current is coupled to the external terminal 40A. The selector 45 interchanges coupling relations between the two input terminals of the selector 45 and the two output terminals of the selector 45 (i.e., the two input terminals of the comparator 44) by control by the control logic 43. The comparator 44 outputs, to the control logic 43, a difference between two signals inputted via the selector 45.

A reference resistor 48 is coupled to the external terminal 20B. The reference resistor 48 is inserted between the external terminal 40B and the fixed voltage line VSS. The resistance value Rref of the reference resistor 48 is Zo, for example. In a case where the input impedance of the replica circuit 41 is adjusted, the constant current source Ibgr that supplies a constant current is coupled the external terminal 40B.

### [Impedance Adjustment]

Next, description is given of input impedance adjustment in the receiver 2.

First, the control logic 43 searches for an impedance code Code1 that causes the variable resistor element 42 of replica circuit 41 to become Zo. Specifically, first, the user couples the constant current source Itester that supplies a constant current to the external terminal 40A, and couples the constant current source Ibgr that supplies a constant current to the external terminal 40B. Subsequently, the control logic 43 inputs the initial value of the impedance code Code1 to the variable resistor element 42 of the replica circuit 41. This causes a resistance value R42 of the variable resistor element 42 of the replica circuit 41 to be set to a resistance value R0 corresponding to the initial value of the impedance code Code1. Furthermore, a predetermined constant current from the constant current source Itester coupled to the external terminal 40A is supplied to the variable resistor element 42 of the replica circuit 41, and a predetermined constant current from the constant current source Ibgr coupled to the external terminal 40B is supplied to the reference resistor 48. As a result, an input voltage V41 of the replica circuit 41 (=a voltage V40A of the external terminal 40A) becomes a predetermined voltage value (Itester×R0), and a voltage V40B of the external terminal 40B becomes a predetermined voltage value (Ibgr×Rref=the reference voltage Vref). The voltage (=the voltage V40A) of the input line L10 and the voltage (=the reference voltage Vref) of the input line L11 are inputted to the comparator 44, and a signal corresponding to the voltage ΔV1 (=V40A−Vref) of a difference between these voltages is inputted from the comparator 44 to the control logic 43. The control logic 43 sets the impedance code Code1 to a value that causes the voltage ΔV1 to approach zero, and outputs the value after such setting to the variable resistor element 42 of the replica circuit 41. The control logic 43 resets the impedance code Code1 until the voltage ΔV1 becomes zero (or a value close to zero and within an allowable range). Consequently, when the voltage ΔV1 becomes zero (or the value close to zero and within the allowable range), the control logic 43 stores the set value at that time as the impedance code Code1 in the memory 47. Thus, the control logic 43 searches for the impedance code Code1 that causes the variable resistor element 42 of replica circuit 41 to become Zo.

Next, the control logic 43 interchanges input to the comparator 44. Specifically, the control logic 43 inputs a control signal to the selector 45 to thereby interchange coupling relations between the two input terminals of the selector 45 and the two output terminals of the selector 45 (i.e., the two input terminals of the comparator 44).

The control logic 43 then searches for the impedance code Code2 that causes the variable resistor element 42 of the replica circuit 41 to become Zo, by a method similar to the method described above. Thereafter, the control logic 43 derives, on the basis of the impedance codes Code1 and Code2, the impedance code Code in which an influence of an offset of the comparator 44 is reduced. The control logic 43 derives the impedance code Code in which the influence of the offset of the comparator 44 is reduced, with use of the following expression, for example.

Code=Code1−(Code1−Code2)/2

The control logic 43 stores the derived impedance code Code in the memory 47. The control logic 43 outputs the impedance code Code read from the memory 47 to the driver circuit 30 to thereby control the input impedance of the driver circuit 30 (e.g., the variable resistor element 31).

### [Effects]

Next, description is given of effects of the receiver 2 according to the present embodiment.

In the present embodiment, impedances of the variable resistor elements 31 and 42 are adjusted on the basis of a comparison result between the reference voltage Vref, which is generated by coupling the constant current source Ibgr to the external terminal 40B, and the input voltage V41 of the replica circuit 41 (=the voltage V40A of the external terminal 40A). This makes it possible to adjust an input impedance of the driver circuit 30 while avoiding an influence of a contact resistance in the external terminal 40B. This consequently makes it possible to reduce trimming errors, as compared with a case where a constant voltage source is used.

In addition, in the present embodiment, the impedances of the variable resistor elements 31 and 42 are adjusted on the basis of a comparison result, by the comparator 44, between the reference voltage Vref, which is generated by flowing, into the reference resistor 48, of a current from the constant current source Ibgr coupled to the external terminal 40B, and the input voltage V41 of the replica circuit 41 (=the voltage V40A of the external terminal 40A). This makes it possible to adjust the input impedance of the driver circuit 30 while avoiding the influence of the contact resistance in the external terminal 40B. This consequently makes it possible to reduce trimming errors, as compared with a case where a constant voltage source is used.

In addition, in the present embodiment, the impedances of the variable resistor elements 31 and 42 are adjusted on the basis of a comparison result, by the comparator 44, between the input voltage V41 of the replica circuit 41, which is generated by flowing, into the replica circuit 41, of a current from the constant current source Itester coupled to the external terminal 40A, and the reference voltage Vref. This makes it possible to adjust the input impedance of the driver circuit 30 while avoiding the influence of the offset of the comparator 44. This consequently makes it possible to reduce trimming errors, as compared with a case where a constant voltage source is used.

In addition, in the present embodiment, the impedances of the variable resistor elements 31 and 42 are adjusted on the basis of respective comparison results of the voltage (the voltage V40A) of the input line L10 and the voltage (the reference voltage Vref) of the input line L11 obtained before and after interchange of input points to the comparator 44 by the selector 45. This makes it possible to adjust the input impedance of the driver circuit 30 while reducing the influence of the offset of the comparator 44. This consequently makes it possible to reduce trimming errors, as compared with a case where a constant voltage source is used.

### 4. Third Embodiment

### [Configuration]

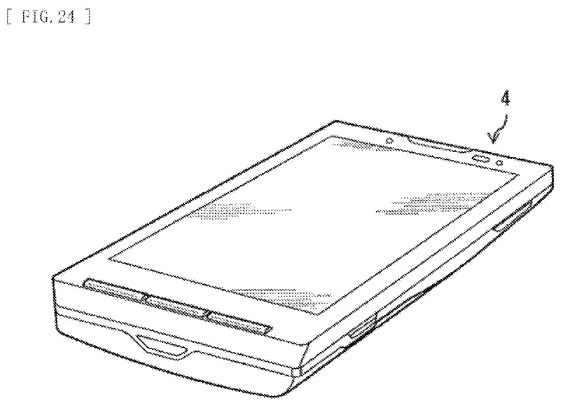

Description is given of a communication system 3 according to a third embodiment of the present disclosure. FIG. 23 illustrates a schematic configuration example of the communication system 3. The communication system 3 includes the transmitter 1 according to any of the above-described first embodiment and the modification examples thereof, and the receiver 2 according to the above-described second embodiment. The transmitter 1 and the receiver 2 are electrically coupled to each other via transmission lines Lane0 to Lanen. One end of each of the transmission lines Lane0 to Lanen is coupled to each external terminal 10A of the transmitter 1, and another end of each of the transmission lines Lane0 to Lanen is coupled to each external terminal 30A of the receiver 2. In the present modification example, impedance matching is performed between both the transmitter 1 and the receiver 2 and the transmission lines Lane0 to Lanen. This makes it possible to achieve communication with high transmission efficiency.

### 4. Application Examples

In the following, description is given of application examples of the transmitter 1, the receiver 2, and the communication system 3 according to the above-described respective embodiments and the modification examples thereof.

### Application Example 1

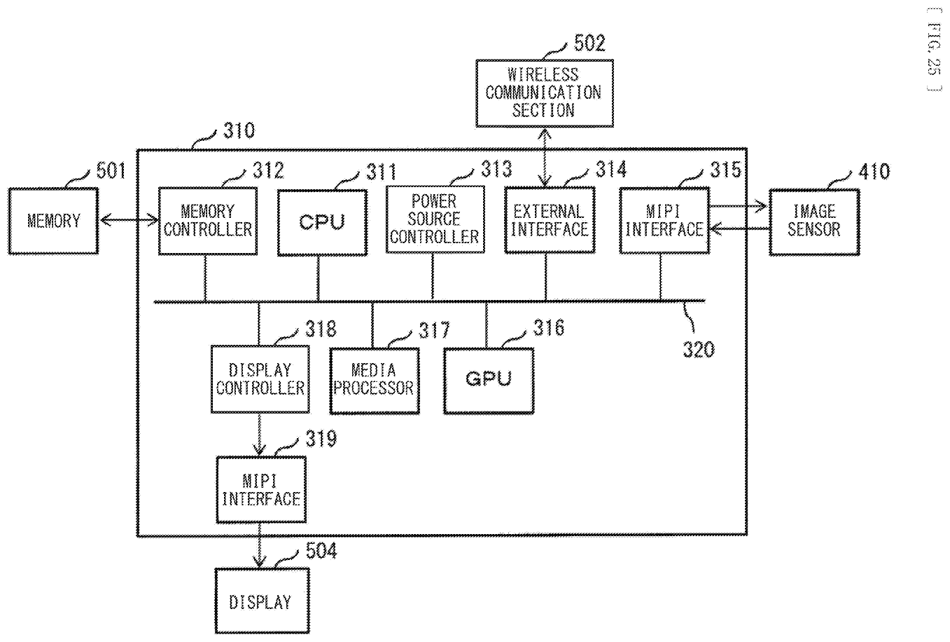

FIG. 24 illustrates an appearance of a smartphone 4 (a multifunctional mobile phone) to which the transmitter 1, the receiver 2, and the communication system 3 according to the above-described respective embodiments and the modification examples thereof are applied. Various devices are mounted in the smartphone 4. The transmitter 1, the receiver 2, and the communication system 3 according to the above-described respective embodiments and the modification examples thereof are applied to a communication system in which data are exchanged among these devices.

FIG. 25 illustrates a configuration example of an application processor 310 to be used in the smartphone 4. The application processor 310 includes a CPU (Central Processing Unit) 311, a memory controller 312, a power source controller 313, an external interface 314, an MIPI interface 315, a GPU (Graphics processing Unit) 316, a media processor 317, a display controller 318, and an MIPI interface 319. In this example, the CPU 311, the memory controller 312, the power source controller 313, the external interface 314, the MIPI interface 315, the GPU 316, the media processor 317, and the display controller 318 are each coupled to a system bus 320 to allow for data exchange with one another via the system bus 320.

The CPU 311 processes various pieces of information handled in the smartphone 4 in accordance with a program. The memory controller 312 controls a memory 501 to be used when the CPU 311 performs information processing. The power source controller 313 controls a power source of the smartphone 4.

The external interface 314 is an interface for communication with external devices. In this example, the external interface 314 is coupled to a wireless communication section 502. The wireless communication section 502 performs wireless communication with mobile phone base stations. The wireless communication section 502 includes, for example, a baseband section, a RF (radio frequency) front end section, and the like.

The MIPI interface 315 receives an image signal from an image sensor 410. For example, the communication system 3 according to any of the above-described respective embodiments and the modification examples thereof is applied to a communication system between the MIPI interface 315 and the image sensor 410. The image sensor 410 acquires an image, and includes a CMOS sensor, for example.

The GPU 316 performs image processing. The media processor 316 processes information such as voice, characters, and graphics. The display controller 317 controls a display 504 via the MIPI interface 319.

The MIPI interface 319 transmits an image signal to the display 504. As the image signal, for example, a YUV-format signal, an RGB-format signal, or any other format signal is used. For example, the transmitter 1, the receiver 2, and the communication system 3 according to the above-described respective embodiments and the modification examples thereof are applied to a communication system between the MIPI interface 319 and the display 504.

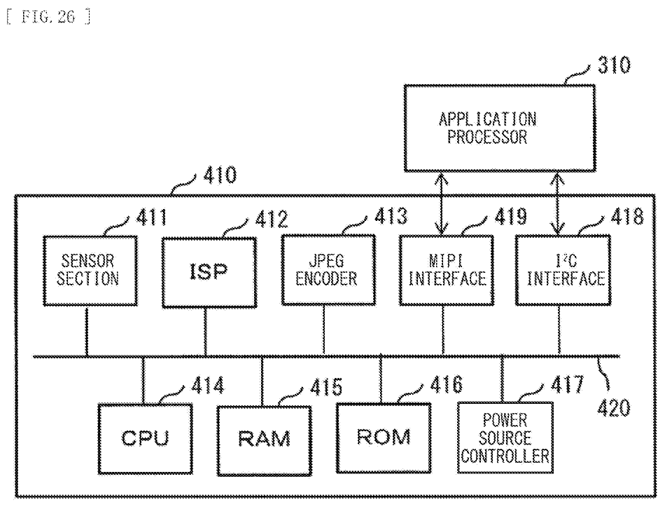

FIG. 26 illustrates a configuration example of the image sensor 410. The image sensor 410 includes a sensor section 411, an ISP (Image Signal Processor) 412, a JPEG (Joint Photographic Experts Group) encoder 413, a CPU 414, a RAM (Random Access Memory) 415, a ROM (Read Only Memory) 416, a power source controller 417, an I2C (Inter-Integrated Circuit) interface 418, and an MIPI interface 419. In this example, these respective blocks are coupled to a system bus 420 to allow for data exchange with one another via the system bus 420.

The sensor section 411 acquires an image, and includes, for example, a CMOS sensor. The ISP 412 performs predetermined processing on the image acquired by the sensor section 411. The JPEG encoder 413 encodes the image processed by the ISP 412 to generate a JPEG-format image. The CPU 414 controls respective blocks of the image sensor 410 in accordance with a program. The RAM 415 is a memory to be used when the CPU 414 performs information processing. The ROM 416 stores a program to be executed in the CPU 414. The power source controller 417 controls a power source of the image sensor 410. The I2C interface 418 receives a control signal from the application processor 310. In addition, although not illustrated, the image sensor 410 also receives a clock signal from the application processor 310, in addition to the control signal. Specifically, the image sensor 410 is configured to be operable on the basis of clock signals with various frequencies.

The MIPI interface 419 transmits an image signal to the application processor 310. As the image signal, for example, a YUV-format signal, an RGB-format signal, or any other format signal is used. For example, the transmitter 1, the receiver 2, and the communication system 3 according to the above-described respective embodiments and the modification examples thereof are applied to a communication system between the MIPI interface 419 and the application processor 310.

### Application Example 3

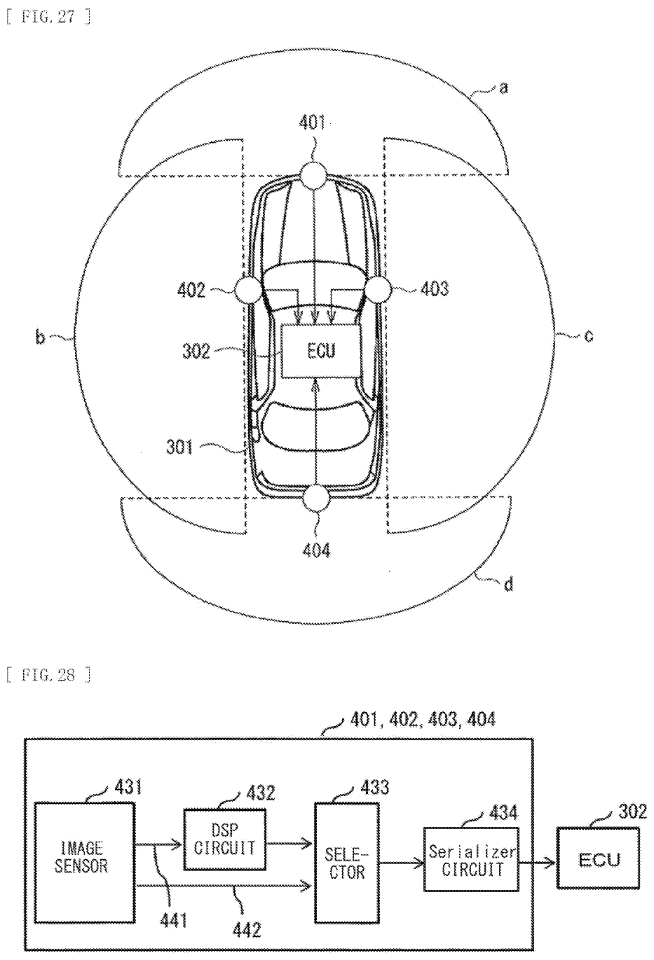

FIG. 27 and FIG. 28 each illustrate a configuration example of a vehicle-mounted camera as an application example to an imaging device. FIG. 27 illustrates an installation example of the vehicle-mounted camera, and FIG. 28 illustrates an internal configuration example of the vehicle-mounted camera.

For example, vehicle-mounted cameras 401, 402, 403, and 404 are respectively mounted on the front (front), left, right, and rear (rear) of a vehicle 301, as illustrated in FIG. 27. The vehicle-mounted cameras 401 to 404 are each coupled to an ECU (Electrical Control Unit) 302 via an in-vehicle network.

An image capturing angle of the vehicle-mounted camera 401 mounted on the front of the vehicle 301 is within a range indicated by “a” in FIG. 22, for example. An image capturing angle of the vehicle-mounted camera 402 is within a range indicated by “b” in FIG. 22, for example. An image capturing angle of the vehicle-mounted camera 403 is within a range indicated by “c” in FIG. 22, for example. An image capturing angle of the vehicle-mounted camera 404 is within a range indicated by “d” in FIG. 22, for example. Each of the vehicle-mounted cameras 401 to 404 outputs a captured image to the ECU 302. This consequently makes it possible to capture a 360-degree (omnidirectional) image on the front, left, right, and rear of the vehicle 301 in the ECU 302.

For example, each of the vehicle-mounted cameras 401 to 404 includes an image sensor 431, a DSP (Digital Signal Processing) circuit 432, a selector 433, and a SerDes (SERializer-DESerializer) circuit 434, as illustrated in FIG. 28.

The DSP circuit 432 performs various types of image signal processing on an imaging signal outputted from the image sensor 431. The SerDes circuit 434 performs serial-parallel conversion of a signal, and includes, for example, a vehicle-mounted interface chip such as FPD-Link III.

The selector 433 selects whether to output the imaging signal outputted from the image sensor 431 via the DSP circuit 432 or not via the DSP circuit 432.

Any of the communication systems according to the above-described respective embodiments is applicable to, for example, a coupling interface 441 between the image sensor 431 and the DSP circuit 432. Moreover, the transmitter 1, the receiver 2, and the communication system 3 according to the above-described respective embodiments and the modification examples thereof are applicable to, for example, a coupling interface 442 between the image sensor 431 and the selector 433.

Although the present disclosure has been described above referring to a plurality of embodiments and the modification examples thereof, the disclosure is not limited to the above-described embodiments and the like, and may be modified in a variety of ways. It is to be noted that effects described in the specification are merely illustrative. The effects of the present disclosure are not limited to those described in the specification. The present disclosure may have effects other than those described in the specification.

In addition, the present disclosure may have the following configurations.

(1)

An impedance adjustment method being a method of adjusting an impedance of a first variable resistor element in a semiconductor device, the semiconductor device including an output driver, a replica circuit, a first wiring line, a second wiring line, and a comparator, the output driver including the first variable resistor element, the replica circuit including a second variable resistor element and having the same configuration as the output driver, the first wiring line coupled to an output end of the replica circuit, the second wiring line electrically coupled to a first external terminal, the comparator that compares a voltage of the first wiring line with a voltage of the second wiring line, the impedance adjustment method including:

adjusting impedances of the second variable resistor element and the first variable resistor element on the basis of a comparison result, by the comparator, between a reference voltage and an output voltage of the replica circuit, the reference voltage being generated by coupling a first constant current source to the first external terminal.

(2)

The impedance adjustment method according to (1), in which the first wiring line is electrically coupled to a second external terminal, and in the impedance adjustment method, the impedances of the second variable resistor element and the first variable resistor element are adjusted on the basis of a comparison result, by the comparator, between the output voltage of the replica circuit and the reference voltage, the output voltage of the replica circuit being generated by flowing, into the replica circuit, of a current from a second constant current source coupled to the second external terminal.

(3)

The impedance adjustment method according to (1) or (2), in which the semiconductor device includes a reference resistor element electrically coupled to the first external terminal, and in the impedance adjustment method, the impedances of the second variable element and the first variable element are adjusted on the basis of a comparison result, by the comparator, between the reference voltage and the output voltage of the replica circuit, the reference voltage being generated by flowing, into the reference resistor element, of a current from the first constant current source coupled to the first external terminal.

(4)

The impedance adjustment method according to any one of (1) to (3), in which the semiconductor device further includes a selector that interchanges input points, to the comparator, of the voltage of the first wiring line and the voltage of the second wiring line, and in the impedance adjustment method, the impedances of the second variable resistor element and the first variable resistor element are adjusted on the basis of the comparison result obtained each of before and after interchange of the input points by the selector.

(5)

An impedance adjustment method being a method of adjusting an impedance of a first variable resistor element in a semiconductor device, the semiconductor device including an output driver, a replica circuit, a first wiring line, a second wiring line, a third wiring line, a reference resistor, a first selector, and a comparator, the output driver including the first variable resistor element, the replica circuit including a second variable resistor element and having the same configuration as the output driver, the first wiring line coupled to an output end of the replica circuit, the second wiring line electrically coupled to a first external terminal, the third wiring line electrically coupled to a second external terminal, the reference resistor including a third variable resistor element electrically coupled to a fourth wiring line, the first selector that couples one of the first wiring line and the third wiring line to the fourth wiring line, the comparator that compares a voltage of the fourth wiring line with a voltage of the second wiring line, the impedance adjustment method including:

adjusting impedances of the second variable resistor element and the first variable resistor element on the basis of:

a first comparison result, by the comparator, between a reference voltage generated by coupling a first constant current source to the first external terminal, and a voltage generated by flowing, into the reference resistor, of a current via the third wiring line and the first selector, the current being generated by coupling a second constant current source to the second external terminal, and

a second comparison result, by the comparator, between the reference voltage generated by coupling the first constant current source to the first external terminal, and an output voltage of the replica circuit obtained via the first selector and the fourth wiring line in a state in which the third variable resistor element is coupled to the fourth wiring line.

(6)

The impedance adjustment method according to (5), in which

the semiconductor device includes a reference resistor element coupled to the first external terminal, and

in the impedance adjustment method, the impedances of the second variable resistor element and the first variable resistor element are adjusted on the basis of:

a first comparison result, by the comparator, between the reference voltage generated by flowing, into the reference resistor element, of a current from the first constant current source coupled to the first external terminal, and a voltage generated by flowing, into the reference resistor, of a current via the third wiring line and the first selector, the current being generated by coupling the second constant current source to the second external terminal, and

a second comparison result, by the comparator, between the reference voltage generated by flowing, into the reference resistor element, of the current from the first constant current source coupled to the first external terminal, and an output voltage of the replica circuit obtained via the first selector and the fourth wiring line in a state in which the third variable resistor element is separated from the fourth wiring line.

(7)

The impedance adjustment method according to (5) or (6), in which

the semiconductor device includes a second selector that interchange input points, to the comparator, of one of a voltage of the first wiring line and a voltage of the third wiring line, and the voltage of the second wiring line, and

in the impedance adjustment method, includes the impedances of the second variable resistor element and the first variable resistor element are adjusted on the basis of the second comparison result obtained each of before and after interchange of the input points by the second selector.

(8)

An impedance adjustment method being a method of adjusting an impedance of a first variable resistor element in a semiconductor device, the semiconductor device including an output driver, first and second replica circuits, a first wiring line, a second wiring line, a third wiring line, a first reference resistor, a second reference resistor, a fourth wiring line, a third reference resistor, a selector, and a comparator, the output driver including the first variable resistor element, the first and second replica circuits including a second variable resistor element and having the same configuration as the output driver, the first wiring line coupled to an output end of the first replica circuit, the second wiring line electrically coupled to a first external terminal, the third wiring line electrically coupled to a second external terminal, the first reference resistor including a third variable resistor element electrically coupled to the third wiring line, the second reference resistor including a fourth variable resistor element electrically coupled to the first wiring line, the fourth wiring line coupled to an output end of the second replica circuit, the third reference resistor including a fifth variable resistor element electrically coupled to the fourth wiring line, the selector that selects one of the first wiring line, the third wiring line, and a first constant voltage line and one of the second wiring line, the fourth wiring line, and a second constant voltage line, the comparator that compares two voltages outputted from the selector with each other, the impedance adjustment method including:

adjusting impedances of the second variable resistor element and the first variable resistor element on the basis of:

a first comparison result, by the comparator, between a reference voltage generated by coupling a first constant current source to the first external terminal, and a voltage generated by flowing, into the first reference resistor, of a current generated by coupling a second constant current source to the second external terminal,

a second comparison result, by the comparator, between an output voltage of the first replica circuit in a state in which the fourth variable resistor element is coupled to the first wiring line, and a voltage of the second constant voltage line, and

a third comparison result, by the comparator, between an output voltage of the second replica circuit in a state in which the fifth variable resistor element is coupled to the fourth wiring line, and a voltage of the first constant voltage line.

(9)

The impedance adjustment method according to (8), in which

the semiconductor device includes a reference resistor element coupled to the first external terminal, and

in the impedance adjustment method, the impedances of the second variable resistor element and the first variable resistor element are adjusted on the basis of a first comparison result, by the comparator, between the reference voltage generated by flowing, into the reference resistor element, of a current from the first constant current source coupled to the first external terminal, and a voltage generated by flowing, into the first reference resistor, of a current generated by coupling the second external terminal to a second constant current source, the second comparison result, and the third comparison result.

(10)

A semiconductor device including:

an output driver including a first variable resistor element;

a replica circuit including a second variable resistor element and having the same configuration as the output driver;

a first wiring line coupled to an output end of the replica circuit;

a second wiring line electrically coupled to a first external terminal; and

a comparator that compares a voltage of the first wiring line with a voltage of the second wiring line.

(11)

The semiconductor device according to (10), further including a reference resistor element coupled to the first external terminal.

(12)

The semiconductor device according to (10) or (11), in which the first wiring line is coupled to a second external terminal.

(13)

The semiconductor device according to any one of (10) to (12), further including a selector that interchanges input points, to the comparator, of the voltage of the first wiring line and the voltage of the second wiring line.

(14)

A semiconductor device including:

an output driver including a first variable resistor element;

a replica circuit including a second variable resistor element and having the same configuration as the output driver;

a first wiring line coupled to an output end of the replica circuit;

a second wiring line electrically coupled to a first external terminal;

a third wiring line electrically coupled to a second external terminal;

a reference resistor including a third variable resistor element electrically coupled to a fourth wiring line;

a first selector that couples one of the first wiring line and the third wiring line to the fourth wiring line; and

a comparator that compares a voltage of the fourth wiring line with a voltage of the second wiring line.

(15)

The semiconductor device according to (14), further including a reference resistor element coupled to the first external terminal.

(16)

The semiconductor device according to (14) or (15), further including a second selector that interchanges input points, to the comparator, of one of voltages of the first wiring line and the third wiring line, and the voltage of the second wiring line.

(17)

A semiconductor device including:

an output driver including a first variable resistor element;

first and second replica circuits including a second variable resistor element and having the same configuration as the output driver;

a first wiring line coupled to an output end of the first replica circuit;

a second wiring line electrically coupled to a first external terminal;

a third wiring line electrically coupled to a second external terminal;

a first reference resistor including a third variable resistor element electrically coupled to a third wiring line;

a second reference resistor including a fourth variable resistor element electrically coupled to the first wiring line;

a fourth wiring line coupled to an output end of the second replica circuit;

a third reference resistor including a fifth variable resistor element electrically coupled to the fourth wiring line;

a selector that couples one of the first wiring line, the third wiring line, and a first constant voltage line to one of the second wiring line, the fourth wiring line, and a second constant voltage line; and

a comparator that compares two voltages outputted from the selector with each other.

(18)

The semiconductor device according to (17), further including a reference resistor element coupled to the first external terminal.

According to first, second, and third impedance adjustment methods and first, second, and the third semiconductor devices according to embodiments of the present disclosure, it is possible to adjust output impedances of the second variable resistor element and the first variable resistor element while avoiding an influence of a contact resistance. This makes it possible to reduce trimming errors. It is to be noted that the effects of the present disclosure are not necessarily limited to the effects described herein, and may be any of the effects described in the specification.

This application claims the benefit of Japanese Priority Patent Application JP2018-077340 filed with the Japan Patent Office on Apr. 13, 2018, the entire contents of which are incorporated herein by reference.

It should be understood by those skilled in the art that various modifications, combinations, sub-combinations and alternations may occur depending on design requirements and other factors insofar as they are within the scope of the appended claims or the equivalents thereof.

1. An impedance adjustment method being a method of adjusting an impedance of a first variable resistor element in a semiconductor device, the semiconductor device including an output driver, a replica circuit, a first wiring line, a second wiring line, and a comparator, the output driver including the first variable resistor element, the replica circuit including a second variable resistor element and having a same configuration as the output driver, the first wiring line coupled to an output end of the replica circuit, the second wiring line electrically coupled to a first external terminal, the comparator that compares a voltage of the first wiring line with a voltage of the second wiring line, the impedance adjustment method comprising:
adjusting impedances of the second variable resistor element and the first variable resistor element on a basis of a comparison result, by the comparator, between a reference voltage and an output voltage of the replica circuit, the reference voltage being generated by coupling a first constant current source to the first external terminal.

2. The impedance adjustment method according to claim 1, wherein
the first wiring line is electrically coupled to a second external terminal, and
in the impedance adjustment method, the impedances of the second variable resistor element and the first variable resistor element are adjusted on a basis of a comparison result, by the comparator, between the output voltage of the replica circuit and the reference voltage, the output voltage of the replica circuit being generated by flowing, into the replica circuit, of a current from a second constant current source coupled to the second external terminal.

3. The impedance adjustment method according to claim 1, wherein
the semiconductor device includes a reference resistor element electrically coupled to the first external terminal, and
in the impedance adjustment method, the impedances of the second variable element and the first variable element are adjusted on a basis of a comparison result, by the comparator, between the reference voltage and the output voltage of the replica circuit, the reference voltage being generated by flowing, into the reference resistor element, of a current from the first constant current source coupled to the first external terminal.

4. The impedance adjustment method according to claim 1, wherein
the semiconductor device further includes a selector that interchanges input points, to the comparator, of the voltage of the first wiring line and the voltage of the second wiring line, and
in the impedance adjustment method, the impedances of the second variable resistor element and the first variable resistor element are adjusted on a basis of the comparison result obtained each of before and after interchange of the input points by the selector.

5. An impedance adjustment method being a method of adjusting an impedance of a first variable resistor element in a semiconductor device, the semiconductor device including an output driver, a replica circuit, a first wiring line, a second wiring line, a third wiring line, a reference resistor, a first selector, and a comparator, the output driver including the first variable resistor element, the replica circuit including a second variable resistor element and having a same configuration as the output driver, the first wiring line coupled to an output end of the replica circuit, the second wiring line electrically coupled to a first external terminal, the third wiring line electrically coupled to a second external terminal, the reference resistor including a third variable resistor element electrically coupled to a fourth wiring line, the first selector that couples one of the first wiring line and the third wiring line to the fourth wiring line, the comparator that compares a voltage of the fourth wiring line with a voltage of the second wiring line, the impedance adjustment method comprising:
adjusting impedances of the second variable resistor element and the first variable resistor element on a basis of:
a first comparison result, by the comparator, between a reference voltage generated by coupling a first constant current source to the first external terminal, and a voltage generated by flowing, into the reference resistor, of a current via the third wiring line and the first selector, the current being generated by coupling a second constant current source to the second external terminal, and
a second comparison result, by the comparator, between the reference voltage generated by coupling the first constant current source to the first external terminal, and an output voltage of the replica circuit obtained via the first selector and the fourth wiring line in a state in which the third variable resistor element is coupled to the fourth wiring line.

6. The impedance adjustment method according to claim 5, wherein
the semiconductor device includes a reference resistor element coupled to the first external terminal, and
in the impedance adjustment method, the impedances of the second variable resistor element and the first variable resistor element are adjusted on a basis of:
a first comparison result, by the comparator, between the reference voltage generated by flowing, into the reference resistor element, of a current from the first constant current source coupled to the first external terminal, and a voltage generated by flowing, into the reference resistor, of a current via the third wiring line and the first selector, the current being generated by coupling the second constant current source to the second external terminal, and
a second comparison result, by the comparator, between the reference voltage generated by flowing, into the reference resistor element, of the current from the first constant current source coupled to the first external terminal, and an output voltage of the replica circuit obtained via the first selector and the fourth wiring line in a state in which the third variable resistor element is separated from the fourth wiring line.

7. The impedance adjustment method according to claim 6, wherein
the semiconductor device includes a second selector that interchange input points, to the comparator, of one of a voltage of the first wiring line and a voltage of the third wiring line, and the voltage of the second wiring line, and
in the impedance adjustment method, includes the impedances of the second variable resistor element and the first variable resistor element are adjusted on a basis of the second comparison result obtained each of before and after interchange of the input points by the second selector.

8. An impedance adjustment method being a method of adjusting an impedance of a first variable resistor element in a semiconductor device, the semiconductor device including an output driver, first and second replica circuits, a first wiring line, a second wiring line, a third wiring line, a first reference resistor, a second reference resistor, a fourth wiring line, a third reference resistor, a selector, and a comparator, the output driver including the first variable resistor element, the first and second replica circuits including a second variable resistor element and having a same configuration as the output driver, the first wiring line coupled to an output end of the first replica circuit, the second wiring line electrically coupled to a first external terminal, the third wiring line electrically coupled to a second external terminal, the first reference resistor including a third variable resistor element electrically coupled to the third wiring line, the second reference resistor including a fourth variable resistor element electrically coupled to the first wiring line, the fourth wiring line coupled to an output end of the second replica circuit, the third reference resistor including a fifth variable resistor element electrically coupled to the fourth wiring line, the selector that selects one of the first wiring line, the third wiring line, and a first constant voltage line and one of the second wiring line, the fourth wiring line, and a second constant voltage line, the comparator that compares two voltages outputted from the selector with each other, the impedance adjustment method comprising:
adjusting impedances of the second variable resistor element and the first variable resistor element on a basis of:
a first comparison result, by the comparator, between a reference voltage generated by coupling a first constant current source to the first external terminal, and a voltage generated by flowing, into the first reference resistor, of a current generated by coupling a second constant current source to the second external terminal,
a second comparison result, by the comparator, between an output voltage of the first replica circuit in a state in which the fourth variable resistor element is coupled to the first wiring line, and a voltage of the second constant voltage line, and
a third comparison result, by the comparator, between an output voltage of the second replica circuit in a state in which the fifth variable resistor element is coupled to the fourth wiring line, and a voltage of the first constant voltage line.

9. The impedance adjustment method according to claim 8, wherein
the semiconductor device includes a reference resistor element coupled to the first external terminal, and
in the impedance adjustment method, the impedances of the second variable resistor element and the first variable resistor element are adjusted on a basis of a first comparison result, by the comparator, between the reference voltage generated by flowing, into the reference resistor element, of a current from the first constant current source coupled to the first external terminal, and a voltage generated by flowing, into the first reference resistor, of a current generated by coupling the second external terminal to a second constant current source, the second comparison result, and the third comparison result.

10. A semiconductor device comprising:
an output driver including a first variable resistor element;
a replica circuit including a second variable resistor element and having a same configuration as the output driver;
a first wiring line coupled to an output end of the replica circuit;
a second wiring line electrically coupled to a first external terminal; and
a comparator that compares a voltage of the first wiring line with a voltage of the second wiring line.

11. The semiconductor device according to claim 10, further comprising a reference resistor element coupled to the first external terminal.

12. The semiconductor device according to claim 11, wherein the first wiring line is coupled to a second external terminal.

13. The semiconductor device according to claim 12, further comprising a selector that interchanges input points, to the comparator, of the voltage of the first wiring line and the voltage of the second wiring line.

14. A semiconductor device comprising:
an output driver including a first variable resistor element;
a replica circuit including a second variable resistor element and having a same configuration as the output driver;
a first wiring line coupled to an output end of the replica circuit;
a second wiring line electrically coupled to a first external terminal;
a third wiring line electrically coupled to a second external terminal;
a reference resistor including a third variable resistor element electrically coupled to a fourth wiring line;
a first selector that couples one of the first wiring line and the third wiring line to the fourth wiring line; and
a comparator that compares a voltage of the fourth wiring line with a voltage of the second wiring line.

15. The semiconductor device according to claim 14, further comprising a reference resistor element coupled to the first external terminal.

16. The semiconductor device according to claim 15, further comprising a second selector that interchanges input points, to the comparator, of one of voltages of the first wiring line and the third wiring line, and the voltage of the second wiring line.

17. A semiconductor device comprising:
an output driver including a first variable resistor element;
first and second replica circuits including a second variable resistor element and having a same configuration as the output driver;
a first wiring line coupled to an output end of the first replica circuit;
a second wiring line electrically coupled to a first external terminal;
a third wiring line electrically coupled to a second external terminal;
a first reference resistor including a third variable resistor element electrically coupled to a third wiring line;
a second reference resistor including a fourth variable resistor element electrically coupled to the first wiring line;
a fourth wiring line coupled to an output end of the second replica circuit;
a third reference resistor including a fifth variable resistor element electrically coupled to the fourth wiring line;
a selector that couples one of the first wiring line, the third wiring line, and a first constant voltage line to one of the second wiring line, the fourth wiring line, and a second constant voltage line; and
a comparator that compares two voltages outputted from the selector with each other.

18. The semiconductor device according to claim 17, further comprising a reference resistor element coupled to the first external terminal.
